(19) United States
(12) Patent Application Publication
(10) Pub. No.: US 2020/0342932 A1
(43) Pub. Date: Oct. 29, 2020

(54) NAND CONNECTED GAIN CELL MEMORY

(71) Applicant: John Bennett, Sammamish, WA (US)

(72) Inventor: John Bennett, Sammamish, WA (US)

(21) Appl. No.: 16/896,057

(22) Filed: Jun. 8, 2020

Related U.S. Application Data
(63) Continuation-in-part of application No. 16/395,081, filed on Apr. 25, 2019, now abandoned.

(51) Int. Cl. G11C 11/4096; G11C 11/4074; G11C 11/4091; H01L 27/108

(52) U.S. Cl. CPC G11C 11/4096; G11C 11/4074; H01L 27/10826; H01L 27/10814; G11C 11/4091

(57) ABSTRACT

Memory systems and techniques for efficiently storing data are described herein. A memory system may include a memory string of multiple dynamic memory cells, with each cell having an access transistor connecting a data-input-line to a capacitive element, an output transistor connected to the capacitive element, with the output transistors of the multiple cells having channels connected in series forming a stacked-gate transistor, and a read-select-line connected to the capacitive element, where a change in voltage on the read-select line controls voltage on the capacitive element. The memory system also includes a read-string-select-line connecting in series the channels of the output transistors of the cells, and a data-output-line connected to the stacked-gate transistor, such that to access data stored in the cells, the read-select-line of the cells is set to a neutral level to cause the output of the output transistor of the cells to be detectable on the data-output-line.

### CROSS-REFERENCE TO RELATED APPLICATIONS

This application is a continuation-in-part of U.S. patent application Ser. No. 16/395,081, filed on Apr. 25, 2019, entitled “NAND CONNECTED GAIN CELL MEMORY,” the disclosure of which is hereby incorporated herein in its entirety.

### BACKGROUND

The original conception of the dynamic random access memory cell (DRAM) was by Robert Dennard at IBM in 1968. It was dynamic because there would be leakage of charge from the capacitor and so a periodic read and rewrite operation would be needed for restoring the correct charge levels, to accurately store bits for varying time periods. It had a destructive read-out requiring the data to be rewritten or refreshed after being read (which was a familiar requirement since magnetic core memory had destructive reads, also). Sensing circuits eventually made that refresh an intrinsic part of sensing the output.

This design was not translated into a commercial product until several years later, but it became the standard design, and variants of this design suitable for evolving device processes have dominated the DRAM market, in large part because this design provides smallest cell and can be fabricated with the largest number of cells per chip.

It took a few years before this 1 transistor 1 capacitor per cell design (1T1C) became the norm in commercial use, in large part because the physical designers had to master techniques for adding adequately sized capacitors to the logic process. Designs descended from Dennard's idea account for more than 99% of RAM memory bits. An exemplary diagram of a Dennard 1T1C cell is illustrated in FIG. 1.

The first commercially successful DRAM was the Intel 1103 in 1971, an exemplary diagram of which is illustrated in FIG. 2. It used a 3 transistor cell which stored charge on the intrinsic capacitance of the gate of the second transistor (T2) and had a non-destructive readout so there was no need to rewrite a cell every time you read it. In this “3T1C” design, the dynamic nature is that charge leaks away from the gate capacitor and needs to be restored by a refresh cycle. The read out was not destructive so it did not require data to be rewritten each time it was read. This was a gain cell, although the terminology was coined later.

This design became commercially available and successful before Dennard's design in part because, in 1971, the non-destructive read was a significant simplification, and because it did not require the separate steps of chip processing needed to form a capacitor. Over time, those advantages faded relative to the size advantage of Dennard's design. 3T1C designs still have some use in embedded memory where their size and speed are a reasonable balance, and compatibility with processes used for logic chips makes it possible to put them beside related logic blocks on the same chip.

Accordingly, improvements can be made in the field of dynamic memory.

### BRIEF DESCRIPTION OF THE DRAWINGS

FIG. 1 illustrates an exemplary diagram of a one transistor, one capacitor (1T1C) Dynamic Random Access Memory (DRAM) cell.

FIG. 2 illustrates an exemplary diagram of a three transistor, one capacitor (3T1C) Dynamic Random Access Memory (DRAM) cell.

FIG. 3 illustrates an example schematic of a two transistor, one capacitor memory cell.

FIG. 4 illustrates another example schematic of a two transistor, one capacitor multi-level memory cell.

FIG. 5 illustrates an example schematic of multiple memory cells arranged in a string and connected by an output NAND structure.

FIG. 6 illustrates an example schematic of multiple strings of memory cells connected by an output NAND structure arranged in an array.

FIG. 7 illustrates another example schematic of multiple memory cells connected by an output NAND structure arranged in a string.

FIG. 8 illustrates an example schematic of multiple memory cells connected by an output NAND structure in a vertical arrangement.

FIGS. 9A-9I illustrate example stages in the formation of the example arrangement of memory cells of FIG. 8.

FIG. 10 illustrates another example diagram of multiple memory cells connected by an output NAND structure in a vertical arrangement.

FIG. 11 illustrates an example schematic of an array of two transistor, one capacitor memory cells.

FIG. 12 illustrates another example schematic of an array of two transistor, one capacitor memory cells.

FIGS. 13A-13C and 14A-14C illustrate example stages in the formation of an example arrangement of a memory array using finFET technology.

FIGS. 15A-15E illustrate additional example stages in the formation of an example arrangement of a memory array with distinct data in and data out lines.

FIGS. 16A-16C illustrate additional example stages in the formation of the example arrangement of a memory array using a saddle cell design.

FIG. 17 illustrates another example arrangement of a memory array.

FIGS. 18A-18G and 19A-19J illustrate another set of example stages in the formation of an example arrangement of a memory array.

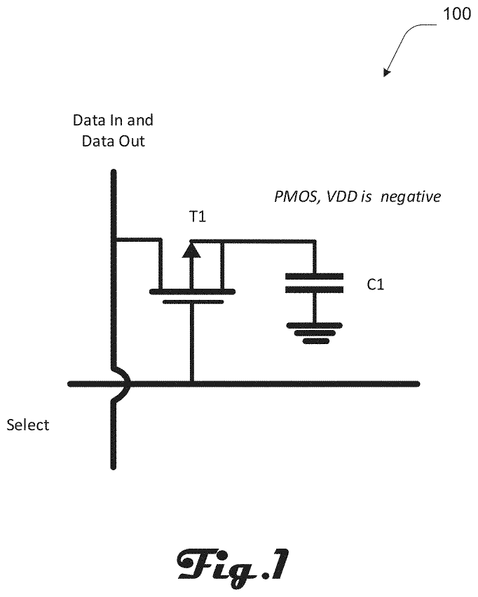

It should be noted that the figures are not drawn to scale and that elements of similar structures or functions are generally represented by like reference numerals for illustrative purposes throughout the figures. It also should be noted that the figures are only intended to facilitate the description of the preferred embodiments. The figures do not illustrate every aspect of the described embodiments and do not limit the scope of the present disclosure.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Techniques described and suggested herein include methods and systems for a random access memory that enables the compact formation of an array of gain cell memory circuits. The described random access memory returns to the gain cell approach and builds upon that to reduce the size of the sense (second) transistors by combining the transistors from adjacent cells. When the channel of the sense transistor runs across multiple cells and each cell has a gate on that channel, then the gates and channel form a stacked-gate transistor commonly known as a NAND transistor. The set of cells which participate in a single NAND may be referred to throughout this disclosure as a NAND “string.”

In some aspects, a further reduction in cell size may be obtained by constructing the cell taking advantage of 3D layering so that the access transistor is in the base layer, the capacitor is above the access transistor, and the sense gates and NAND transistor channels are in a layer above the base layer. If larger capacitors are required for certain applications, the NAND channels and sense gates may be in the middle and the capacitors either trenched into the substrate or trenched into a layer stacked on top. For example, when 4 capacitor layers are used then 4 cells share the same stack of capacitors and each capacitor on its level may spread across the 4 underlying cells, so capacitors are enabled to be larger than the base cells.

In some aspects, an array may include a number of individual gain cells that support accurate writing and reading of multiple levels of charge in a capacitor, representing more than 1 bit of data per cell. A gain cell is a form of electronic dynamic memory which adds sense transistors in each cell to support non-destructive access to the contents of the cell. The read out of the cell provides a higher signal to noise ratio which is compatible with improvements over fully dynamic random access memory (DRAM), such as faster read-out, use of smaller capacitance, and use of various charge levels to represent multiple bits of information per cell.

The described memory cell uses charge storage in a capacitor to store values. A second transistor in each cell is used to sense the charge through the insulating barrier of its gate, such that the act of reading the cell does not remove charge. As a result, there is no need for a refresh cycle to be included in every read, as there is in a fully dynamic random access memory. The sense transistor also amplifies the readout, which improves signal strength. This “gain” feature gives the generally accepted name for this class of dynamic memory cell. Additional transistors and or diodes may be added to a gain cell to enhance signal to noise ratio and for other benefits.

Charge on a conventional capacitor may eventually leak away and need refresh back to original levels. This is done by scheduling reads at intervals short enough that the charge still clearly represents the original value, resolving the correct value, and writing that value back at the full nominal level. This need for refresh is the distinguishing mark of a “dynamic” memory cell.

The gain cell, since it senses the charge on the capacitor without disturbing it and then amplifies that value, may also be used with capacitors which carry a persistent charge. An example of this kind of capacitor is one with a ferroelectric dielectric (e.g., some dielectrics based on a mix of zirconium and hafnium oxides have ferroelectric properties) which lasts for an indefinite time without a need for refresh, though there may be some need for refresh due to long term disturbances from activity nearby in the array. Such a device is effectively a static memory. The structures described in this disclosure may be either dynamic or static, depending upon the materials used in the capacitor.

The term “word” means a set of cells selected to be read or written in parallel. The “data-lines” are used to read or write data values for individual cells. These organizations usually run across each other at right angles, so one word-line may touch upon a word of many cells, while the data-lines cross that word contacting only one cell in that word. The data-lines may contact cells in other words, but the activation through the word-line is necessary and the other words remain inactive, such that the output value of the active cell may be sensed separately from cells in non-selected words. In the literature, word-lines are sometimes called “select” lines, and “data” lines may be called “cell” or “bit” lines. When the memory is diagrammed as a grid it will often be shown with words running horizontal and referred to as “rows”, while the data-lines are drawn vertically so have come to be called “columns.” This convention is adopted throughout this disclosure.

The described systems and methods introduce a cell design or arrangement with two word-lines crossing two data-lines, to enable selecting the cell and to setting an electrical value representing a piece of information (e.g., a numerical value) in the cell. One word-line is the write enable line or write select line which controls the action of the access transistor which allows charge to flow to the capacitor. The other word-line is the read-enable line or read select line, which is connected to the other pole of each cell capacitor in the row. The capacitors, and the charge on them, are held between these two lines which together orchestrate writing and reading to the cell. Moving charge in or out of the cell through the access transistor is referred to as “writing” or as “programming” the cell.

In some aspects, the cell outputs are connected in strings along all or part of the data-line using a stacked gate or “NAND” transistor for sensing the charge level of the cell and converting it into output on the NAND transistor. This transistor's channel is the thread binding a string of cells together and the string is defined as the set of cells which share a NAND channel. This structure may provide for more compact implementation and sharing of overhead. The NAND strings are orthogonal to the word-line. The NAND transistor channel is a local spur of a longer data-out line, connecting each cell in the string to the data-out line.

Via the structure of the gain cell, the output may be selected separately from the input. This allows for the cell to be programmed while different cells are being read, or when no cells are being read. This structure also allows for cells to be read when no cell is being programmed. In some cases, selecting for output requires both that the read-select lines be set to appropriate values for each cell in the string, and that the NAND channel for the string be enabled to draw power which the sense gates can modulate.

When this structure is implemented for a multi-level cell, the output of a gain cell may be read at the same time as the input value is being written, as disclosed in U.S. patent application Ser. No. 16/221,170, titled “SYSTEM FOR ACCURATE MULTIPLE LEVEL GAIN CELLS,” filed Dec. 14, 2018, the contents of which are herein incorporated by reference in their entirety, as if fully set forth herein. This may be used to monitor the output from a cell while it is being programmed to provide feedback on reaching a charge in the cell which results in accurate output from the cell. This feedback can compensate for variations in the cells to ensure that the output which is delivered matches the nominal, regardless of variations in cell, gain transistors, and intervening elements.

The feedback loop monitoring the output level will include the characteristics of the neighboring elements in the NAND channel, so their losses may be compensated by the actual value written into the cell being programmed.

If the cells are being used only to store one bit, then feedback is less important, as the cell may simply be programmed with a maximum or minimum value possible to represent two levels. Implementing the gain cell in this way, only storing one bit, can yield a simpler and faster memory cell. Also, with this minimal approach, the cell will also have the longest time between refreshes while safely distinguishing between the two values. Persistent cells may have a dielectric requiring full range on or off to obtain hysteresis, so depending upon their physics, they may also store only one bit and not need a feedback loop.

One benefit of using a stacked-gate transistor for the sense gates is the denser structure of the gain transistor, as a NAND usually can be constructed with a single linear channel passing all the cells in the string, each cell having a gate in contact with that channel. Rules keeping spacing between gates are minimal in most integrated circuit processes because NAND is a valuable construct, so this assures that the gain gate will add minimal overhead to the underlying 1T1C memory cell.

In some aspects, the two data lines may be combined into a single data line which serves both input and output. The data line is connected to the access channels for input, while the output transistors are formed upon the data line to modulate it for output. In some aspects, the data output line may be formed from semiconductor materials which have their conductivity enhanced by use of alloyed material such as silicon germanium, or higher conductivity pure materials such as germanium, which may in addition be doped with trace elements suitable for enhancing its NAND operation. When the data input line is separate it may be of any conductive material, but when it is a unified single data line for both input and output it will be a semiconductor, which may be of a material chosen for high conductivity NAND operation.

The cell capacitors in the described memory cells connect between the end of the access transistor inside the memory cell, and a read-select line. The value at the output of the cell is thus a delta caused by the charge trapped on the capacitor when the access transistor is inactive, relative to the voltage on the read-select line. The default state of the read-select lines of cells is to be set to an “everything off” value where the gate voltage on the sense transistor will be “off”, no matter what delta is due to internal charge of the cell. This keeps the NAND inactive and minimizes the load on the data-output line, since only the final stage in the stacked-gate transistor presents any load on the data-output.

This approach is also space saving relative to the original gain cell, in part because the wire or line connecting to the opposite pole of the cell capacitor will normally not be competing for critical space in the active layer of silicon. It may be placed running overhead in a separate layer. In the classic gain cell, the routing of the second word-line posed a significant problem expanding the area of the memory cell which is largely avoidable in the described design.

In some aspects, the capacitor may be cylindrical above the access transistor as an insulated tunnel through some thickness of conductor that is the read-select line, with the central conductor of the capacitor terminating above the read select line. The sense gate can then be formed on top with a NAND channel running over the top of the cells. This vertical construction minimizes the 2-D layout size of each cell.

When a cell is being read, a different pattern of voltages is applied to the set of read-lines for words which intersect the strings in which a cell is to be read. For the read-lines in that set which are not being read, the read-select lines are set to a value which causes the sense gates to be “always on” regardless of the delta due to charge in those cells. For the read-line which connects to the capacitors of the word being read, the read-line is set to a “sensing” or neutral voltage where the charge within those cells will be able to modulate the sense gate. Because all the other sense-gates will be biased to always-on, which makes their channel conductive, the overall state of the stacked-gate or NAND transistor will be controlled by the sense gate of the cell being read. This is repeated for each string which includes the word which the read-select line connects to.

In addition, the operation of the NAND gate may be conditional upon pass-through gates which connect to the data-out line. Even if the word-lines are set to values to read a cell, the cell must also be selected for active connection to the data-out. This may mean that only a subset of the cells in a word are active for a given operation.

The strings may be of limited length, such as including 4, or 10, or 32, or some other number of cells with sense gates upon the stacked-gate or NAND transistor. This count is balanced by considering that a string with few cells will have a better signal quality, while a string of many cells will have proportionally less overhead due to shared elements, such as the connections to data-lines. There may be many such strings in parallel (e.g., horizontally as will be descried in greater detail below), which together form a stripe of words that operate together, where the same word-lines for write-select and read-select run across the stripe and attach to equivalent cells in each string. In the other direction, there may be multiple strings with their stacked-gate transistors attached to a data-out line which crosses the stripes to include one string from every stripe. The lines may also be buffered or segmented to balance length, loading, size, and performance. Design choices, such as sizes and performance goals for the circuits may inform the specific implementations chosen for certain applications.

In some aspects, extra strings of cells may be inserted at intervals into each stripe. These extras cells may be reference cells, which serve to track the decay in each word and adjust the thresholds between the nominal levels for read-out to reflect the decay over the length of time that word has been stored since its most recent programming or refresh. These reference cells do not hold data but may improve the accuracy of deciding the data value in neighboring data cells.

In some aspects, the capacitor may be a distinct capacitor similar to that used in a DRAM, or it may be some other kind of charge storage structure. With the smaller capacitance permitted by using a sense gate, it may be possible to use non-volatile capacitors, such as using ferro-electric capacitors. In this example, one side of the capacitance device will connect to the word read-select line, while the other side shall connect to the channel of the access (input) transistor and to the gate for the sensing transistor.

Gain cell designs early on settled into use of the intrinsic capacitance of the sense gate to remain small. A distinct capacitor is quite important for storing multi-level data-in one cell, and control of the external side of the capacitor with the read-select line is part of the operation of the NAND structure for shared outputs. The capacitor may be either a passive kind with a dielectric, or the more space efficient space-charge intrinsic of a dummy gate, or a combination of both.

With a gain cell, even a smaller 1 fF capacitor can store 3,000 electrons for a 0.5V potential, and the non-destructive buffered readout introduces the possibility of distinguishing many levels of data per cell. A 16-level cell storing 4 bits of data at 3,000 electrons for full range would have differences of 200 electrons per step in value. That is a large enough number to be reliably programmed and sensed. Even at 3,000 electrons, the charge needed is far smaller than in conventional 1T1C DRAMs, where the charge can be 50,000 electrons or more. The difference is due to the gain at the sense gate. The gain, and signal to noise ratio, increases with slower, more accurate reading that can integrate the signal over longer intervals. Accordingly, much more data can be stored in a smaller area chip layout using a multi-level gain cell.

To obtain linear wide-range output from the cell, instead of using the Drain terminal of the sense FETs, as is the case in nearly all gain cell literature, the Source may be used. The Drain output model offers the highest gain and narrow threshold, which is why it has been the norm. The “Source follower” circuit, which may be implemented in some aspects in the described memory cell/array, has lower gain, but when combined with a constant current load it will have almost linear characteristics. In some cases, a CMOS version can span almost the entire operational range of voltage with near-unity voltage gain, while still safeguarding the charge in the capacitor. The near unity gain enables maximizing the charge range used in the cell capacitor.

This wide range linear gain enables a means for accurate programming of the precise charge level necessary to get the desired level of output. The key to this is that the word-lines for both write and read may be enabled simultaneously, which will result in the source-follower sensing circuit reporting out the data level in real time while the input sets the charge. As a result, the output can be used as it arrives at the analog to digital conversion circuit for negative feedback to a nearby input driver to ensure the input converges to a level where the output at the converter matches the nominal value it is designed to resolve. This nominal value is well defined and stable, while the feedback loop includes all the elements of the cell path which are included in reading out the cell. Once convergence is complete and the write-select line is disabled, the access (T1, input) transistors become non-conductive and the capacitor will retain the charge necessary to recreate that same accurate nominal value each time the cell is read.

The correction for variable elements in the path includes the NAND output from the gain cells. The feedback mechanism will adjust the levels in each cell to produce the correct output level with the neighbors included in the loop.

This design is still dynamic and the charge does leak away over time, unless a non-volatile capacitor is used. If a volatile capacitor is used, the value must be refreshed (read, resolved, and rewritten to recreate the nominal level) before the charge level changes beyond recognition. During that interval, from program to refresh, the output level will change and ideally the nominal levels can be adjusted to track the expected changes. This can be achieved with the reference cells which are inserted among the data cells. In some cases, only a small number of reference cells may be needed for a larger array. For example, one reference cell may be included per 36 cells in a word, or some other repeating count. The reference cells may be constructed exactly or similar to data cells, such that they track the same conditions as the data cells, for the most accurate adjustment of nominal values to match data cell changes over time. The reference cells may have reference values in them, not values related to the user data. These standard values may be written at the same time or nearly the same time as data and become adjuncts to the data word. As the values in the reference cells change over time, the values can be fed into circuits which use the change to adjust the thresholds between the nominal levels expected out of data cells. The thresholds may decline in some formula predictable by the decline of the nearby reference cell values. In some aspects, empirical data may be used to determine or approximate this formula, and either reduce the number or eliminate the need all together for reference cells in memory arrays having similar characteristics.

In some aspects, error correction and redundancy may be incorporated into a practical, competitive device. For example, the word may include extra data cells which contain redundancy codes for correction algorithms such as a parity based ECC, or a maximum likelihood, or low density parity code. Codes such as these detect incorrect data and restore the most likely correction. This feature may be particularly suitable for handling transient errors. The error correction may be in the chips which connect to the memory chip or may be incorporated on the memory chip itself. Multi-level cells may work best with correction codes designed for maximum effectiveness on the kinds of errors most likely found in multi-level cells, which will be different from the most likely errors in 1-bit cells.

When fixed, repeatable errors are found, the redundancy codes can be supplemented by sparing hardware, which may be swapped for use instead of the broken bits. Various methods can be used to identify repeatedly failing cells. Sparing of rows and columns in memory arrays has been used to address decoders or global look-aside spares, and a similar approach may be applied to the gain cell arrays described herein.

It some cases, the input and output circuits which drive the input and sense the output may become complex and much larger than individual memory cells. It would be impractical to have such complex circuits dedicated to small arrays so that the extra circuits are repeated often and take up too much space on the chip. Each set of input output (IO) circuits may be shared by many cells. In this way the balance of silicon used for memory can remain much larger than the area of silicon needed for the input and output circuits.

In some cases, it may be undesirable for words to be too wide or the number of words in an array to be too large, because as size increase, power needed to drive the word and data-lines increases, and speed and accuracy decreases due to those larger resistances and capacitances in longer lines. In practice, the described memory array be formed on a chip that may be organized into tiles (sometimes called sub-arrays, or mats) where each tile is an optimal sized array of cells, with the number of words and number of cells per word chosen to give the best power, performance, and signal to noise ratio. Each tile may be supported by relay circuits which are themselves smaller than the full input and output circuit needed for driving and sensing data. These relays transfer signals in and out of the tile when that tile is enabled, while tiles that are not enabled are isolated and in a minimum power state. The relays may repeat the data values to and from the full I/O circuits.

In some aspects, it may be important to be able to enable or disable the output of the gate cell without changing the state of the charge on the capacitor and without adding an additional gating device to the output. This may be done by controlling the voltage on the opposite side of the storage capacitor from the cell inside. When the cell is programmed, charge is transferred onto the capacitor to yield the desired signal level and then trapped there when the access transistor channel is disabled. The charge on the capacitor maintains a voltage differential across the capacitor. When the controlling voltage on the opposite side, which will be controlled by the Read Select signal line, changes up or down, the interior side of the capacitor also moves up or down as it maintains the difference. In this way, the Read Select may move into a range where the output (sensing) gate is at a voltage which disables the output transistor channel regardless of the difference on the capacitor, or the Read Select may move into a range where the voltage differential will modulate the output gate and channel between off and on, or the Read Select may be in a range where the output gate and channel are enabled regardless of the voltage difference on the capacitor.

With the described NAND output an additional structure is introduced, a connection through an enabling gate from a sequence of NAND outputs to a longer-distance data line. The NAND channel is connected to the data-out line which crosses words. When the connection is enabled, the NAND channel becomes a spur-line which is part of the data-out line. Multiple cells may be concatenated through the NAND channel, with a gate from each of those cells. The channel may be connected to a voltage and current (power) source at one end, with the other end connecting to the data-line. The number of cells in the NAND and the need for connections at start and end of the channel may organize a stripe of words formed by the side by side strings across the width of a tile. The word-lines (write-select and read-select) are orthogonal to the channels and run along the stripe. The strings are isolated from the data-out line when not in use, by an access transistor which defaults off, so the outputs of cells do not draw current when no word in that stripe is selected and so that loading of the data-out line is minimized by disconnecting inactive strings. This is a form of segmented data-line with the parasitic load of inactive cells isolated in side-tracks, the NANDs, which are not connected when not active. Only the stripe containing the word which is currently read will be active and connected. The stripes may be smaller than the number of words (rows) in a tile. The words in that stripe which are not being read will have their read-selects biased fully on, while the read-select for the word being read will be at the level permitting charge on the cell to determine the output level.

In some cases, the use of extra transistors intuitively leads to an expectation of larger cells, which is potentially one reason why the gain cell approach has not been developed to a great extent and was abandoned early in favor of higher density designs. However, the discovery of two new factors make it possible that in fact NAND-connected gain cells can be constructed to have higher areal density than other DRAM.

The first factor is that the capacitor limits the size of modern 1T1C DRAMs. The capacitor in the cell is now far larger now than the transistor. This is because the process of reading the charge on the cell involves signal loss, so there must be a large charge to overcome that loss. Progress in reduction of DRAM capacitor size has become very slow, and is increasingly at a cost of reliability, mutual interference, and slower speeds. The gain cell, in the various aspects described here, can use a much smaller, simpler capacitor since the charge will be amplified on output. It also is compatible with the amount of charge stored on persistent capacitors such as those with ferroelectric materials with sizes on the order of 100 square nanometers. This allows static storage with either no refresh or with relatively long intervals between refresh. The reading of data is non-destructive whether the capacitor is conventional or persistent.

Another factor which is limiting the reduction in size of 1T1C DRAM is the increasing mutual disturbance of adjacent cells due to the closer and closer spacing of the word access lines, where cross talk causes adjacent gates to be slightly enabled when a neighbor is fully enabled. In the gain cell design, described herein, in some cases, the read select lines are separate and isolated from the write selects, to reduce or eliminate disturbance when reading. There is also less of a compromise necessary for speed on the completeness of the off state in the design of the access transistor, which can also reduce disturbance. These factors may enable read-optimized designs to be more densely packed than 1T1C designs can be.

The use of small capacitors, which can be fabricated in or above the cell, opens up a key resource, which is the second factor to use the third dimension, above the chip surface. Building the output transistors above the cell keeps the area small. The NAND channels may then be built using semiconductors deposited above or below the access transistors, and above or below the cell capacitors. The access transistors may remain in the original surface of the semiconductor, where the best crystalline quality is obtained and leakage currents are minimized. This leaves space for an output transistor built above. Modern fabrication offers a number of ways this output transistor may be constructed. For example, a high quality film of silicon may be deposited and annealed with a sacrificial nickel trace which has been found to promote single crystal annealing of silicon over distances of more than 100 microns, which is large enough to cover an array of thousands of memory cells. Other semiconductors such as germanium, polysilicon, or semiconductor alloys such as silicon germanium or gallium arsenide may have satisfactory performance to form the output transistors.

In multiple examples, as described below, it will be observed that the capacitors are substantially planar. This is ideal for the use of novel dielectrics which need uniform deposition and simple geometry. In particular these planar designs will be suitable for use with ferro-electric materials. Those enable the cells to hold charge for longer times with rare or no refresh required, and with reduced disturbance effects from adjacent read and write activity. The gain cell output amplifies the static charge stored on the ferro-electric capacitor which enables the capacitor to be quite small, enabling this approach with non-destructive readout to be used as an alternative to static RAM (SRAM), with much higher density.

This disclosure introduces the use of a stacked-output NAND circuit in combination with use of vertical cell construction, which allow the NAND channels to be realized in an ideal form, a continuous straight line in the column direction connecting adjacent NAND outputs to form a bit line across multiple rows of cells. Cell layout with linear geometry aligned over multiple cells is preferred for the highest resolution features that can be made with lithography.

In addition, in some aspects, the NAND channel may be unified with the data input line, so that there is a single bit line which carries data both in and out. In these aspects, the gain (output) transistors modulate the bit line and the cell has non-destructive read-out just as in other gain cells but uses a single line for both input and output, similar to a Dennard cell. This sharing of a single element may benefit designs in some technologies.

In some cases, the cell may more effectively use the third dimension to achieve denser horizontal packing while keeping input and output lines separate. In other cases the input and output lines may be separate but shared with the same function of adjacent cells so as to reduce the number of distinct elements needed to form an array. The paired cells may be activated for input or output at different times so they do not conflict over using the shared line. In some cases, a FinFET base may be used with separate data-in and data-out fins to achieve a denser layout with both data fins shared by adjacent cells.

In processes where memory cells may be on the same chip as other kinds of devices, for example memory cells embedded on a chip in other parts dedicated to FinFET logic circuits, the elements of the memory region may be processed with the same basic technology but some different steps so that the elements are optimized. For example the fins used for access channels in the memory could be optimized for minimal leakage even if that results in slower operation. In general the gain cell may work best with a slow write and a faster read operation, allowing slower access gates with minimal leakage. As another example, the data in and data out fins may be optimized for conductivity to allow long data lines on larger arrays for an increased array capacity. These differences may be obtained for example by using different doping steps in the different parts of the chip, even while sharing steps related to shaping and etching.

### Cell Modulated by Control of the Capacitor Far Voltage

FIG. 3 illustrates an example schematic 300 of a two transistor, one gain or memory cell. Memory cell 300 includes a first or input transistor T1 302, a capacitor or capacitive element C1 304, and a second or sense or output transistor T2 306. The memory cell 300 also includes two word or select lines 308, 310 crossing two data-lines 312, 314, to enable selecting the cell and to setting an electrical value representing a piece of information (e.g., a numerical value) in the cell, via storing charge on the capacitive element C1 304. The write select or enable line 310 controls the action of the access transistor T1 302 which allows charge to flow to the capacitor 304. The read-enable line or read select line 310 is connected to the other pole of the capacitor C1 304. The capacitor C1 304, and the charge stored thereon, are held between these two lines 308 and 310 which together orchestrate writing and reading to the cell. The value at the output of the cell, on data out or data output line 314 is a delta caused by the charge trapped on the capacitor C1 304 when the access transistor T1 302 is inactive, relative to the voltage on the read-select line 308. The sense transistor T2 306 is used to sense the charge through the insulating barrier of its gate, such that the act of reading the charge of capacitor 304 does not remove charge. As a result, there is no need for a refresh cycle to be included in every read, as there is in a fully dynamic random access memory. The sense transistor T2 306 also amplifies the readout, which improves signal strength. In some aspects, a voltage may be supplied to the source of T2 306.

To write data to the memory cell 300, which is represented by storing a specific charge level on the capacitor 304, the write select line 310 is energized to enable transistor T1 302. In addition, read select line 308 may be set to a standard or known value, so that the value input via T1 302 will set a desired difference across the capacitor C1 304, relative to the standard value on the read select line 308, for example allowing the value to be positive or negative symmetric around the read select line voltage when the dielectric is a ferroelectric. A value may then be input and stored on the capacitor 304 via inputting the desired voltage level into the data input line 312. In some cases, the read select line may remain at its default voltage, such as when the cell capacitor uses a simple dielectric.

To read data from the cell 300, which is represented by obtaining a level of the charge stored on the capacitor 304, the read select line 308 may be energized, such as to a standard or known voltage. The value stored in the capacitor C1 304 may then be output through T2 306 to data output line 314. The value out may be indicative of a delta caused by the charge trapped on the capacitor C1 304 when the access transistor T1 302 is inactive, relative to the voltage on the read-select line 308.

Gain cell 300 is an open-drain variant, such that the drain of T2 306 is driving the data-out line 314. The open drain mode offers the largest gain and is optimal for a cell which stores a single bit, needing to distinguish only between off and on, between 0 and 1.

It should be appreciated that the classic approach to controlling gain cell output has required a third transistor or a diode along with modulation of the power available to the output transistor. With the described memory cell, such as cell 300, a novel approach is introduced using control of the terminal of the cell capacitance 304 which is attached to the Read Select line 308, plus the voltage differential due to the charge stored in the cell, together to modulate the gate of the output transistor 306. This form re-thinks the capacitor external voltage as a control signal, which opens new possibilities for physical layout and functional flexibility.

In some aspects, the capacitor C1 304 of the cell may be written with a low or a high charge level, such that the voltage at the gate of T2 306 during reading shall be either disabled or enabled, allowing the cell to be on or off, and thus store one bit. In some cases, the capacitive element may include a persistent or non-volatile storage device, such as a ferroelectric capacitor.

FIG. 4 illustrates another example schematic 400 of a two transistor, one capacitor gain or memory cell. Memory cell 400 shares various aspects with gain cell 300, including reading and writing operations, described above in reference to FIG. 3, however, gain cell 400 is a source-follower variant, such that the source of T2 406 is driving the data-out line 414. The source follower mode allows for multiple charge levels to be stored in the capacitor C1 404, which levels will be tracked linearly by the output transistor T2 406. In this source follower mode, it is possible to store more than 1 bit of information in the cell 400 by storing one of multiple different charge value in the capacitor C1 404. A voltage may be supplied to the gate of T2 406.

It should be appreciated that operation of memory cell 400 may follow that of memory cell 300 described above in reference to FIG. 3, the main difference being the act of comparing the output to multiple different levels (instead of two values representing a 1 or 0) to determine the value represented by the charge stored on capacitor 404.

In some aspects, T1 and/or T2 of either of circuits 300 or 400 may be P-channel FET devices, N-channel FET devices, or a combination thereof.

In some cases, the capacitive element C1 of either of circuits 300 or 400 may include a capacitor that is separate from the transistors, T1 and T2, such that it includes elements which are not part of the transistors. In yet some cases, the capacitive element C1 may include a buried capacitor such as a trench capacitor. In other cases, the capacitive element may include an overlying capacitor such as a capacitor formed with wires available in the metal connective layers, or a planar capacitor, or a trench capacitor in overlying material layers.

In some aspects, if the read select line 408 is energized to the same standard value for writing as it is for reading, then the value of data out will reflect the value of charge being set in the cell and result in the same value out as will be seen when reading, so long as the charge does not leak away.

### Connecting Sense Gates in a NAND

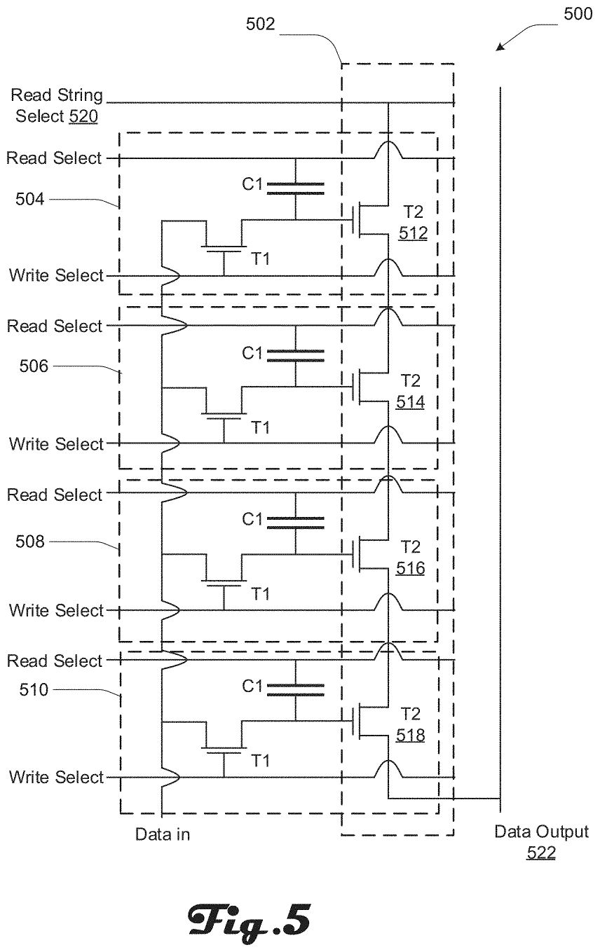

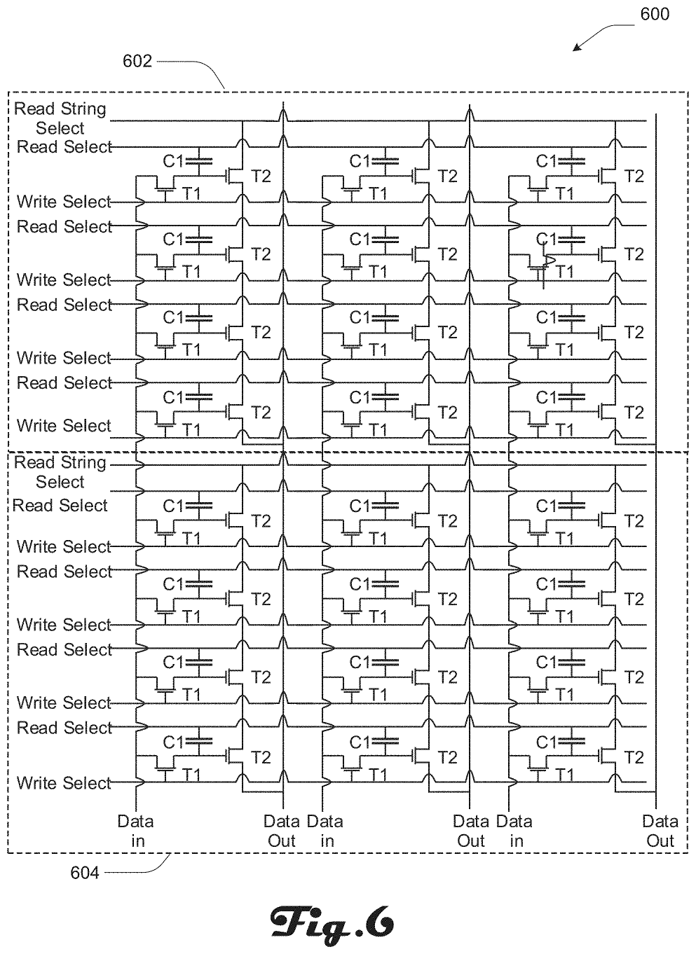

FIG. 5 illustrates an example schematic 500 of multiple gain cells arranged in a string and connected by an output NAND structure 502. Memory string 500 includes 4 memory cells 504, 506, 508, 510, which may each be an example of memory cell 300 or 400, or a combination thereof, as described above in reference to FIGS. 3 and 4.

As illustrated, the sense and selection configuration can be made more compact per gain cell by constructing all the sense transistors 512, 514, 516, 518 of cells 504, 506, 508, 510 as a NAND gate or structure 502 shared with neighboring cells. The NAND structure 502 can be as simple as a single transistor with multiple gates, where the channel of the transistor passes by every cell in the group and each output transistor T2 512, 514, 516, 518 is a gate on that channel, such that the channels of the multiple transistors are continuous. In some aspects, the sense transistor of each cell (individually or as configured in a combined NAND gate structure), such as 512, 514, 516, 518 may be connected in series, where the series is activated by a read select string line 520. Each cell, 506, 508, 510 may individually read, or any combination of multiple cells may be read, as will be described in more detail below, with the output delivered to the data output line 522.

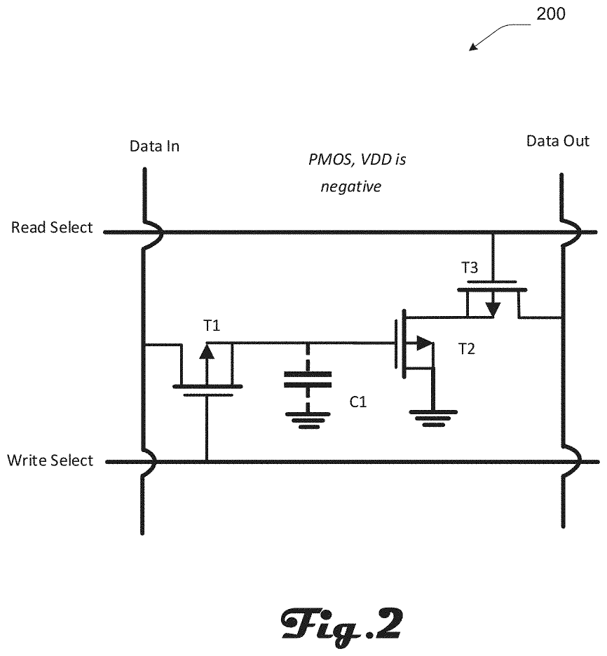

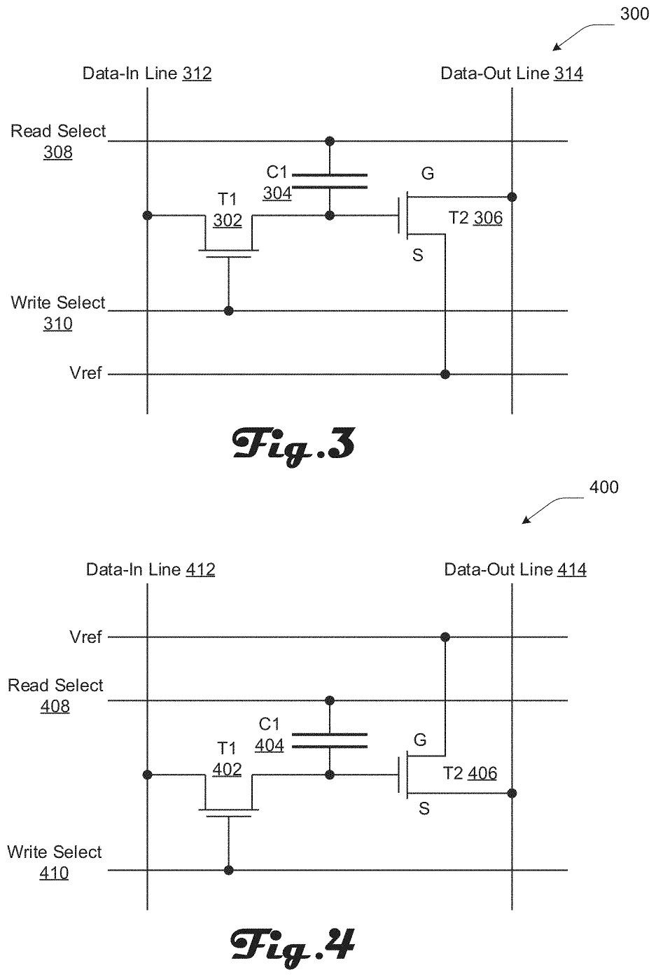

As illustrated in FIG. 5, the NAND structure 502 is shown stacking the T2 transistors 512, 514, 516, 518, of 4 cells 504, 506, 508, 510 but the number of cells in the NAND may differ in practical implementations according to varying design considerations. No separate selection transistor is needed, since the read selection occurs by controlling the opposite pole of the cell capacitor. Effectively the T3, as illustrated in FIG. 2, is eliminated, and the read-select line may be routed in a different layer. In some cases, the two ground (or base level) connections are eliminated in favor or the floating capacitor and the once-per-string read-string-select line.

In some aspects, the NAND transistor 502 is operated in a way which allows individual cells to be read, while maintaining the non-destructive read and other properties of each gain cell. This uses a read-select line connected to the external side of the capacitance of the cells. In some cases, multiple strings may be arranged on a chip horizontally, per the orientation illustrated, as will be described in greater detail below in reference to FIG. 6. In this implementation, each read-select line is a word-line which connects to the cell at the same position in neighboring NAND strings but only one cell in each string. This line is on the opposite side, the select side, of the capacitance of the cell from the inner side, the cell side. The cell side of the capacitance has a charge which is controlled by the access transistor. That charge also controls the voltage upon the channel of T2 (non-conductive), since that gate is also connected to the cell side of the capacitance. If the voltage on the read-select changes, then the charge within the cell maintains a voltage differential due to the captured charge, and so the voltage on the cell side, which is applied to the gate, is the sum of the voltage on the read-select plus the differential.

In some aspects, there are three voltage levels in use for the read-select lines. When “always off”, the read select line is at a voltage such that no matter what differential has been set in the cell, the voltage at the channel of T2 (non-conductive) will be an “off” voltage which make the channel non-conductive. When “always on,” the read-select line has a voltage such that no matter what the differential, the voltage at the channel of T2 (non-conductive) is “on” which will make the channel conductive. When the read-select is at “neutral” voltage, the differential due to charge in the cell make the difference between off and on voltages at the channel of T2 (non-conductive), so the cell value may be sensed at the output.

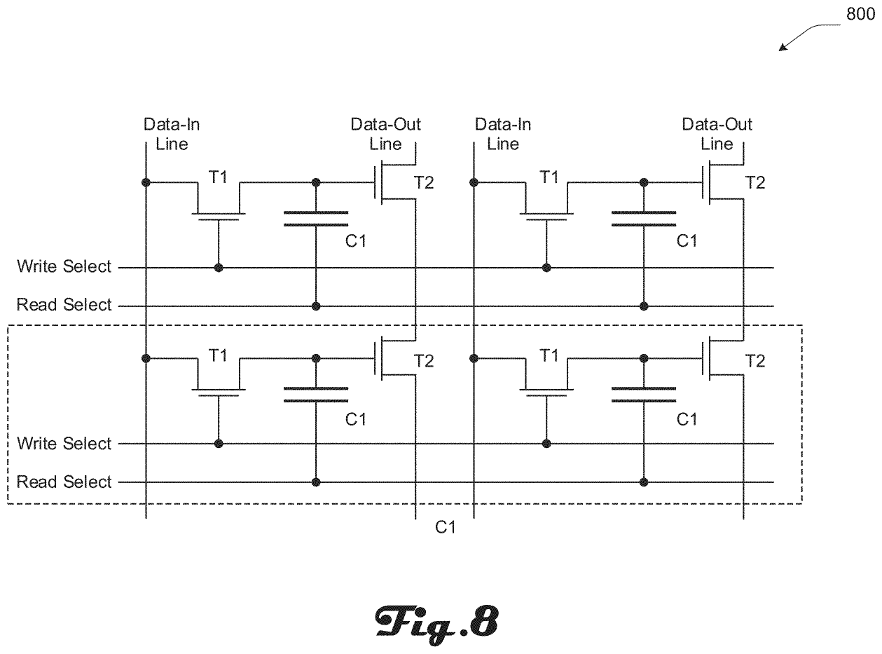

When nothing is being read, all read-selects of the cells 504, 506, 508, 510 in the string are fully off so that no current flows through the NAND structure/transistors 502, and additionally the read string select line is not connected to power. Reading the NAND cells begins with identifying the read-select for the word of cells to be read. In some cases, as will be described in greater detail below in reference to FIG. 8, multiple cells may be arranged in stripes, or horizontal groupings spanning one or a number of different vertical strings. To read a specific cell, in a multiple stripe implementation, the stripe may also be selected. The read string select line 520 can be set to active so it is ready to supply power to the NAND transistors 512, 514, 516, 518 of NAND structure 502. The words within that active stripe which are not selected have their read-select lines set to the fully-on level where the gates on those cells will always enable the NAND transistor as it passes under the gate, regardless of the charge differential on the cells. The selected word has its read-select line set to a neutral value where the charge modulates the T2 transistor, so the overall output from the NAND channel will depend upon the charge captured inside that cell. Because the read-selects are active on this string but fully inactive on the strings for other stripes, the output of this NAND transistor is connected to the data-out line while no other stripes are connected because the NAND transistors are inactive. Thus, that one cell determines the value on the entire data-out, and unwanted load on the data-out is minimized.

In some aspects, by itself, linearity may not be enough to overcome the problems of positional and process variation in multiple cells. Positional variation occurs because cells at different locations in the string will be subject to different offset voltages from the transistors before and after them. Process variation typically occurs in many if not all small circuits because of random variations in lithography, doping, and other features. If variation is not compensated for, it may limit the cell arrays to be relatively small (since nearby cells tend to be less different from each other) and to few, more distinct values per cell (since variations will blur the value distributions). The problem of variability has limited the feasibility of multi-valued DRAM cell designs attempted in the past.

One way described herein to address this variation problem from one or more of these causes is to use feedback when programming the values. In one described solution, the word has write-select, read-string-select, and read-select all operating together. The read-selects of the cells of other word-lines in the stripe are set to always-on, just as when reading. The read-select of the cell being written is set to neutral, so that the charge programmed into the cell will affect the value seen at the conversion circuits just the same was when being read when not programming them. The data value seen at the conversion circuits is used as negative feedback relative to the nominal value in order to correct the charge in the cell to give a precise match to the expected output, adjusting for all the elements in the data-output path just as they will be in read operations. After a time for settling, the write-select line is disabled so that the access transistors are off and not conductive, leaving the charge trapped in the cell. The level of charge in the cell will be whatever satisfies the read path to deliver the expected value. Each structural and statistical variation may be compensated for at the time of writing due to this feedback.

In some cases, one or more of the select, data, and power source lines may be pre-charged ahead of the input select or read-select lines so as to improve the performance and accuracy of cell operations under the performance limitations of small features, overcoming in particular delays and voltage settling times due to resistance and capacitance of the signaling lines.

In some aspects, cooled operation may allow for increased number of distinct data values or smaller cells due to slower leakage from the cell capacitance and lower background noise in the measurements. Leaks through the access transistor channel slow roughly 10× for each 30C drop in operating temperature down to about −40C, beyond which other causes of leakage (such as quantum tunneling) may dominate. Slower leaks allow accurate retention of charge over longer intervals.

Grouping NAND Strings into an Array

FIG. 6 illustrates an example schematic of a memory array 600 including multiple strings of gain cells each connected by an output NAND structure.

In some implementations, a memory device may include a large number of memory cells, such as an array of hundred, thousands, even millions of cells. As illustrated, multiple NAND or memory strings can be organized side by side to form a stripe as tall as the NAND outputs, and the stripes can be laid adjacent, so that overall an array is formed. As illustrated, array 600 may include 2 stripes 602, 604. The select lines traverse cells in the same stripe to define words, while the data-lines traverse multiple stripes to provide input and output for individual cells within the word. There may be an additional select line, the read string select line, per stripe which provides power to one end of the NAND channel. This diagram shows 24 data cells. Each NAND stacks the outputs of 4 cells, so there are 6 strings of cells shown with 2 stripes each with 3 strings of cells in this small example of an array.

In some aspects, data may be written to cells of the memory array 600 by activating the write select line for one word while all other write selects are held inactive, which enables T1 in each cell attached to that write select line so that the cell side of capacitor C1 is connected to the data-input line. Individual voltage levels may be provided on the data-input lines which intersect the cells of the enabled word on each data-input, which will set the desired charge into each cell. Next, the write select line may be inactivated for these cells so that T1 in each cell shall be disabled to close their channels against the flow of current and preserve the charge inside C1 substantially constant for a useful period of time. In some aspects, an amount time may delay in between writing and inactivating the write select line to allow for the charge levels to settle within a desired accuracy. In some aspects, data may be read from cells of the array 600 by setting and maintaining a voltage line through which power flows to T2. For the word being read, the read-select line is held at the neutral level where the level of charge stored in the cell will result in a voltage at the gate of sense transistor T2 such that the channel of the NAND at T2 may be anything from off to on so that cell's value decides the value which is transferred from the voltage line to the data-out line.

In some aspects, the default state of the read-select lines is fully inactive. The fully inactive level is a voltage such that no charge differential on C1 shall cause the gate of T2 to be active. The NAND transistor is fully off. The default state of read string selects is no power. For the word to be read, the stripe containing that word is identified and the read string select for that stripe is activated with power. For the stripe containing the word to be read, for the words not being read, the read-select lines are changed to fully active, which is a voltage such that the T2 of the cells will be conductive whatever the charge held in a cell. For the word being read, the read-select line is held at the neutral level where the level of charge stored in the cell will result in a voltage at the gate of sense transistor T2 such that the channel of the NAND at T2 may be anything from off to on so that cell's value decides the value which is transferred from the NAND to the data-out line.

In some aspects, the memory array 600 may support a read operation on one stripe of words to run concurrently with a write operation on a different stripe of words, such that the two stripes have no cells in common. In some cases, read and write operations may be performed on the same word of cells, so that the cell is being read while it is being written, allowing a write with feedback to the input driver circuits so that the value written may be accurately adjusted even in the presence of variations in cells and circuits.

In some aspects array 600 may also include an encoder and digital to analog conversion circuit to supply an ideal voltage on one or several cells, which will represent the bits of the digital value to be written into each cell. In yet some aspects, the array 600 may additionally or alternatively include an analog to digital converter and a set of threshold values to be used to estimate the value level which is currently reported out on the data-output line by a cell when the word read-select mechanism is enabled.

In some aspects, array 600 may include a differential amplifier. Each cell of array 600 may be activated for reading at the same time as activated for writing and the differential amplifier may use negative feedback from the read value to drive the data-input to each cell through its active access transistor T1 to set the accurate charge level on C1, which is tracked by activated T2 and reported out on the data-output line which is connected to the negative feedback of the amplifier. This feedback loop can be designed to avoid oscillation and properly converge to matching the ideal reported read voltage desired for each cell.

In some aspects, each cell string may be connected via a data-input line to a distinct device for writing an ideal value into one cell at a time, with each cell string connected via a data-output line to a device for reading the output signal and comparing it to one or more threshold values for deciding which of several levels the signal is reporting.

In some cases, reference cell strings may be included at regular intervals among the data storing memory strings. These reference cells may be written, exactly as data cells and with the same feedback to obtain the same accuracy, but instead of data they may be written with specially chosen reference values. There may be different reference values used across the chip. For example, there may be reference cells tracking the most negative values, and other references tracing the most positive values. Reference cells may be written at the same time as data cells, so they follow the same context both on length of time since writing and on correlation to local process variations in that region of the chip. These reference values may flow through the same readout chain as the data values, but for purposes of reading, they will be used to adjust the threshold values expected for analog to digital conversion which resolves the bit values stored in the data cells. These threshold values come from circuits which take the reference cell values as input and adjust accordingly. A threshold value generator may take as input the threshold values and the observed drift in one or more reference cells to generate the most likely correct values which are to be used in the analog to digital conversion of data values from cells near to the reference cells. The decisions on data values may be delayed allowing the settled values of the references to propagate their full effect.

In some aspects, there may be 1, 2, or more standard reference values in use, each for a different reference cell, so that accurate inferences about the change in values over time may be made.

In some aspects, a refresh cycle may include using a read, resolve the read into clear data values, optionally apply error correction, and then another cycle to write the value back, with the feedback in use to renew an accurate cell value. The reference values in reference cells may be written whenever data is written, including the write back part of a refresh cycle.

In some aspects, some cells may be read at the same time as the other cells, where a functional circuit uses the changes in the output of the reference cells to adjust thresholds between the nominal values expected from nearby data cells so as to best reflect changes due to leakage over time and process or environmental variations which affect the cells during retention.

In some cases, the nominal values of the reference cells may be set back to their ideal level at the same time the data cells of the word are written. In some aspects, adjusted nominal values may be used to make a best available decision as to the correct value which was stored in the cell.

In some cases, a word may be augmented with additional cells which enable redundancy, error correction, and error detection upon the values in the word when the word is read so as to compensate for the probability of errors. In some implementations, within a period of time short enough that the value in the cells has not become irretrievable, the value shall be read out and a corrected value refreshed into the word at ideal voltage and charge levels. In some cases, the value read may be more reliably established using error correction values in additional cells before the corrected value is refreshed into the word.

Additional cells may be provided in some cases that provide an integrity code such as a CRC which allows errors to be detected so that error correction may be attempted. In some aspects, one or more refresh cycles may be performed when there is no explicit read or write operation occupying the read and write circuits.

### Relaying the String Output

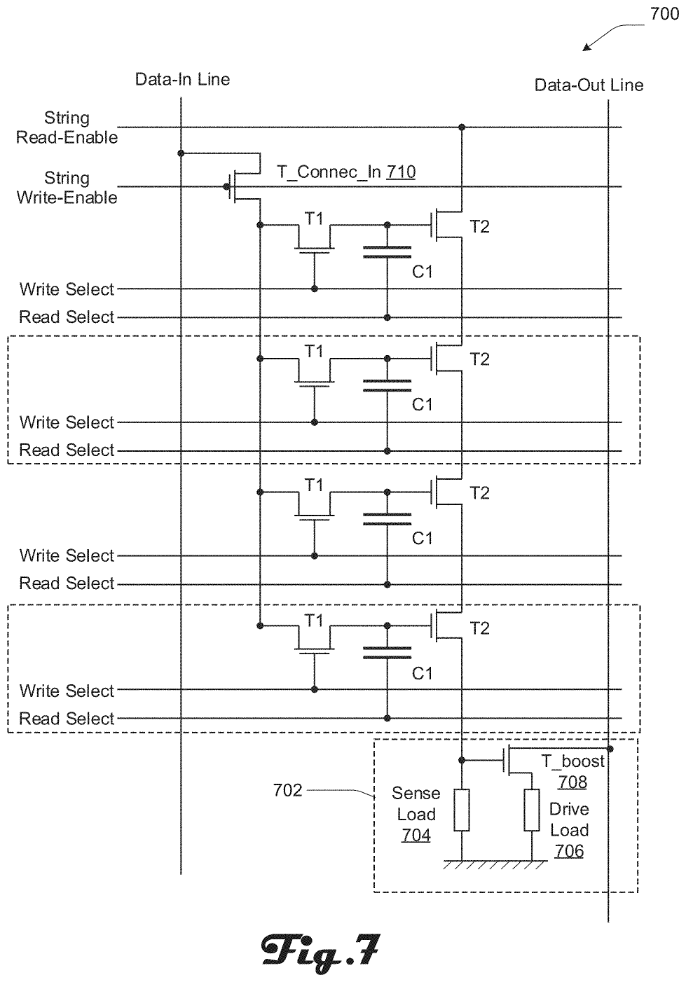

FIG. 7 illustrates another example schematic 700 of multiple gain cells arranged in a string and connected by an output NAND structure. Memory string 700 includes an output circuit or load 702 including a sense or output load 704 and a drive load 706 connected to a boost transistor 708.

In some aspects, the data-input line may be segmented by inserting one or more transistor 710 somewhere between the data cells and the full length of the data-line, which are inactive unless a word on the cell side of the isolating transistor needs to be written, such that only part of the data-line is active at any one time.

It some aspects, it can be an advantage to add further gain, via an output circuit 702, to the output of a memory string, such as memory string 700, as well as to ensure the local read and write select lines are decoupled from the master lines, such as the data output and read string select or enable lines when not in use. Adding an output circuit 702 may further enable the string 700 to have smaller elements, run at lower power, yet still step up to drive a long line across a larger memory array. In some aspects, output circuit may alternatively include a passive impedance load to drain current off the data-output line.

In some aspects, the Sense Load 704 impedance may be selected to be low enough to sink the off leakage in the stacked output, but high enough to generate a tracking output when readout is enabled. The Drive Load 706 may be selected to be low enough to drive the data-out line within the desired settling time. In some aspects, one or more of the loads 704 and 706 may provide a constant or substantially constant current. Transistor 708, T boost, may be connected as a drain driver. In practice, the voltage on the cell will be tracked if the Data-Out line has a complementary current driver larger than the Drive Load 706 can supply, so it will settle close to zero volts from drain to source. In some aspects, the load or output circuit 702 may be implemented to help the output from voltage on the data-out line better track the voltage at the gate of T2 on the cell selected for read in substantially linear form.

In some aspects, where the sense transistors of the cells are configured and connected in source follower mode, using an output circuit 702 may maximize the spread of useful voltage on the capacitance in each cell by reporting it more linearly with near unity voltage gain. Optionally, a constant current load may be driven into the data read line to optimize this benefit while minimizing peak power used. This feature may improve the ability of the cell to hold and read out multiple voltage (charge) levels so that a cell may hold more than one bit of information.

In some aspects, the array 700 may include one or more relay circuits to enable the operation of the array from a distant set of input and output circuits which may include distant digital to analog, writer, reader, and analog to digital circuits. In some aspects, the local relay circuits may connect to local data-input lines and local data-output lines for the cell array 700.

In some aspects, the relay circuits for a cell array 900 may be activated or deactivated, so that the cell array and its circuits are inactive when data stored in that array is not being read or written.

In some aspects, relay circuits may be included for a given number of memory cells/arrays, where the relay circuits may connect to the same distant set of input and output circuit. In some cases, individual relays may be selectable, such that one relay and cell array may operate at one time with the input and output circuits during the period of any one input or output operation.

In some cases, the relay circuits may include an input relay. The input relay may be a linear buffer amplifier which relays and multiplies the voltage of the data-input signal from the distant input circuits. In some cases, the buffer amplifier voltage multiplier may be equal to or close to 1.

In some cases, the output circuits may include an output relay, such as a linear buffer amplifier which relays and multiplies the data-output signal from the local cell array to the distant output circuits.

3D Vertical Connection of Cells with NAND Overhead

FIG. 8 illustrates an example schematic 800 of a partial array of memory cells including 4 memory cells organized into vertical stings and horizontal stripes.

The example arrangement illustrated takes advantage of vertical stacking of elements. As illustrated, this arrangement may also use a simple planar capacitor which will hold on the order of 100 electrons for a 0.5V difference with a 20 nm square unit of layout. This small cell with a simple capacitor may be compatible with logic processes. The uniform deposition of the dielectric layer allows for the use of ferroelectric materials which can benefit from layering, alloying, and doping on the planar surface.

In this approach, the 3D stacking is used to layer different elements on different layers. This should allow the cell size to approach 6F2, which is an optimal case for a DRAM. In effect, the gain stage may be stacked on top of the Dennard stage. The gain allows single line output, not using a balance pair, which in turn simplifies cell layout into a set of horizontal or vertical lanes with no cuts or deviations except for definition of the capacitor. This may provide an optimized and near-ideal arrangement for lithography, such that it increases the efficiency at which a memory device may be produced. An extra gating line may be used with a permanent voltage creating an off region on the access channels. This may make the lithography production process easier and more uniform, without needing an extra step. It completes the regularity of the pattern of the write select gates.

In some aspects, one or more of T2, the data-output line, and the read-select line of one or more cells in the memory array 800 are formed from additional elements of semiconductor, insulator, and conductors which are built substantially above T1 and C1.

In some cases, an electrode of the capacitor may act as the sense gate on the stacked-gate transistor, where the capacitor connection to the access transistor channel of the cell may avoid connection to intervening layers and elements of the cell.

In some implementations, the sense gates and the channel of the stacked-gate transistor may be sited or formed above the other elements of the cell.

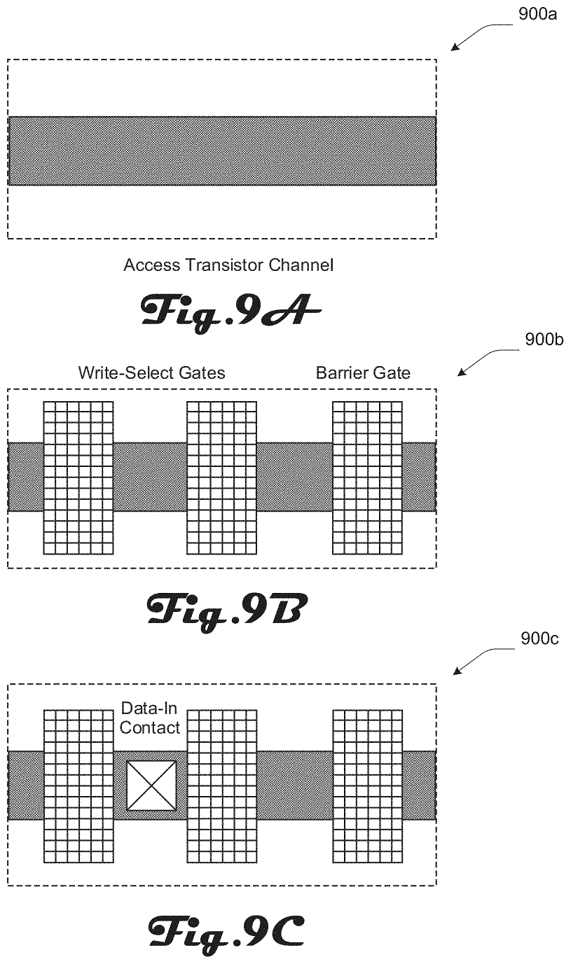

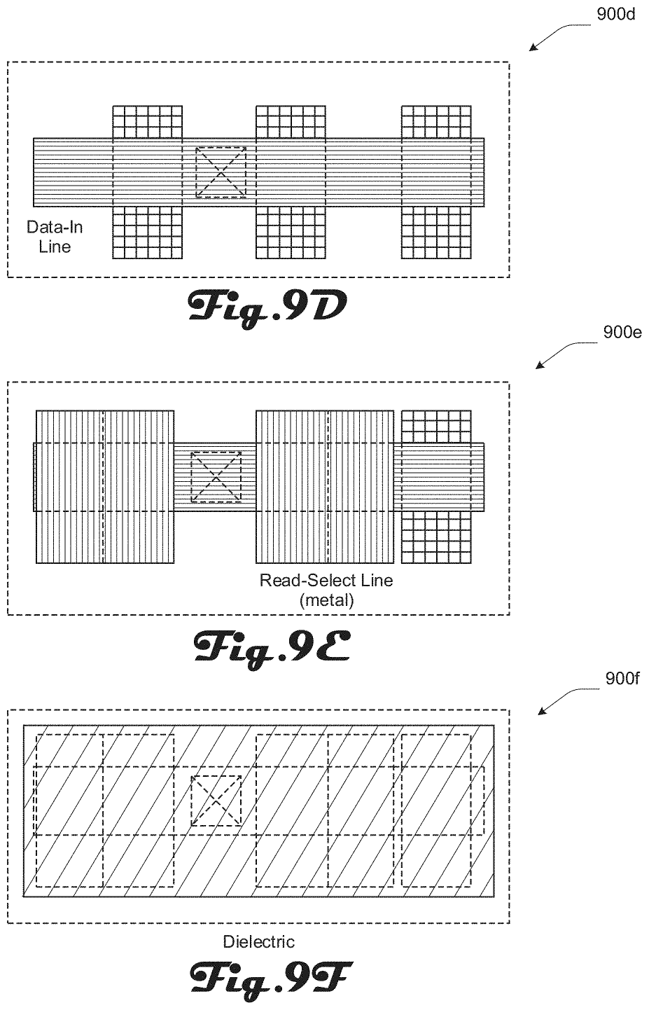

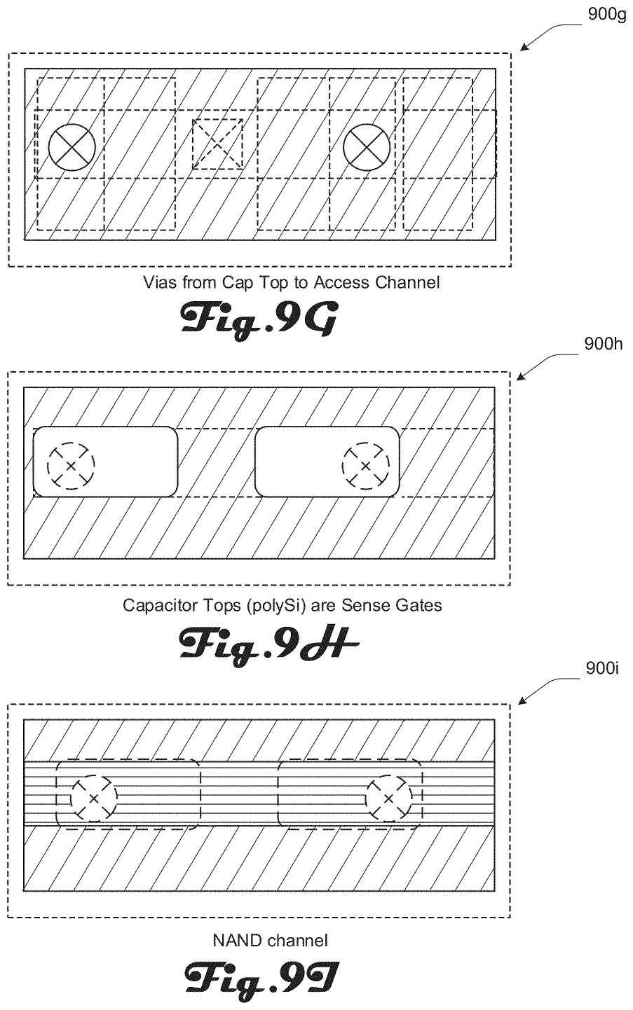

FIGS. 9A-9I illustrate example stages in the formation of an example vertical arrangement of memory cells, such as the arrangement described above in reference to FIG. 8. While the various stages 9A-9I are described in an example order of a process for forming or manufacturing a memory cell as described herein, it should be appreciated that the order of some steps or stages may be modified, some steps may be combined or left out, etc., and other changes made to result in other formation processes contemplated herein.

As illustrated in FIG. 9A, the access transistor channel may be formed on a substrate. In some cases, the channel for the access transistor may be silicon doped to be conductive, either p-channel or n-channel. In some implementations, such as “saddle fin,” this channel is buried.

As illustrated in FIG. 9B, gates may be formed on top of the channel of FIG. 9A. The gates will generally use a layer of an insulating oxide over the channel with polysilicon gates applied above. In saddle fin transistors, there may be some etching into the channel before adding the oxide and gate, which is also buried into the etched region. This results in a wrap-around contact area for a superior performance within the small region. An insulating layer is added over these elements and there may be planarization steps included in the process.

As illustrated in FIG. 9C, a data-in contact may be formed or provided through the insulating layer to the access channel at a point between two write-select gates, so that this central contact may be shared by what are now two transistor channels under the gates on either side of the contact.

As illustrated in FIG. 9D, a data-in line may be added along the direction orthogonal to the write-select gates, on top of the insulation but connected via the data-in contacts to the access transistors. This structure may be covered by an insulating layer.

As illustrated in FIG. 9E, the read-select lines may be added above the insulating layer, running parallel to the write-select lines. These may be as broad as possible, and may be of a variety of conducting materials compatible with capacitor dielectrics, such as but not limited to titanium nitride, doped polysilicon, doped germanium, aluminum, or combinations.

As illustrated in FIG. 9F, a capacitor dielectric compatible with the read-select lines may be deposited above. Suitable dielectrics may include hafnium oxide, zirconium oxide, or other materials with high dielectric constants. Some choices may provide ferro-electric capacitance behavior.

As illustrated in FIG. 9G, one or more contact holes may be etched down to the access-transistor channel at the sides of the write select gates which are opposite to the data-in contact. This hole may be coated with an insulator on its sides, opened at its bottom, and filled with metal to complete a via which will connect the access-transistors to the capacitor top side.

As illustrated in FIG. 9H, the capacitor top sides may be added directly onto the dielectric with contact to the vias. These top plates may be made or formed of a material suitable to be transistor gates, such as polysilicon, or a first layer of capacitor-compatible material (for example, germanium may be preferred when the capacitor dielectric is a ferro-electric with crystal orientation and spacing matching the germanium) with polysilicon on top. A thin gate oxide may be added to these.

As illustrated in FIG. 9I, the silicon or polysilicon channel of the NAND output transistor may be laid on top of the gate oxide perpendicular to the write-select gates, such that the top sides of the capacitor act as gates on this NAND channel. The device may include another layer of oxide and/or passivation and planarization, to isolate it from wiring and other circuit elements may be placed over the top.

In some aspects, cylindrical capacitors may be used instead of these planar forms, where one electrode of the cylinders shall connect through the vias to the end of the access-transistor channel and the other electrode of the capacitor shall be part of the read-select line, while the NAND channel is routed somewhere that the first electrode of the cylinder may be connected to a gate upon the NAND channel. For example, if the first electrode runs through the center of the capacitor then the center may at the top be connected to a polysilicon gate, and the NAND channel be adjacent to, above, or wrapped around that gate.

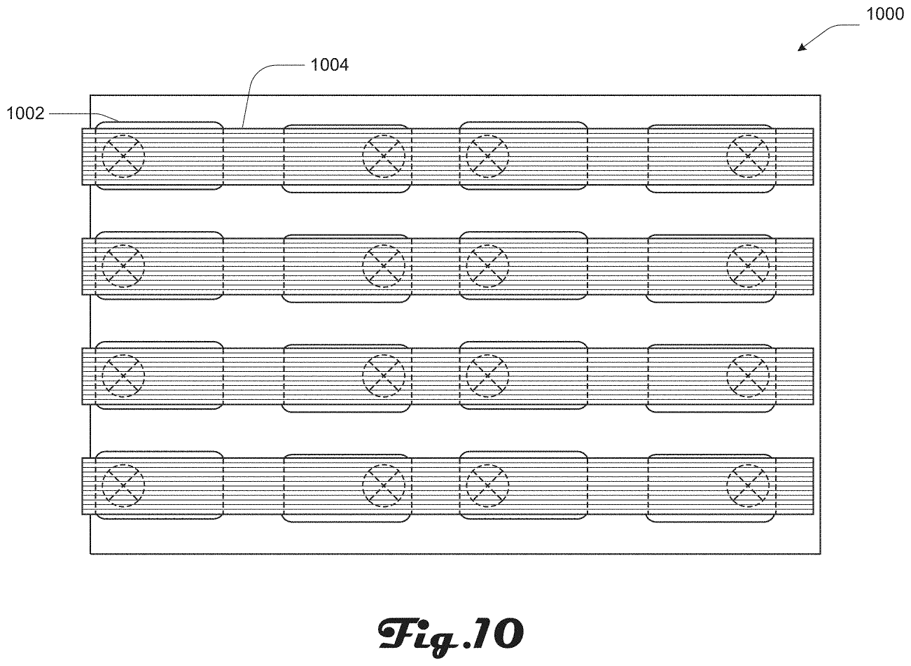

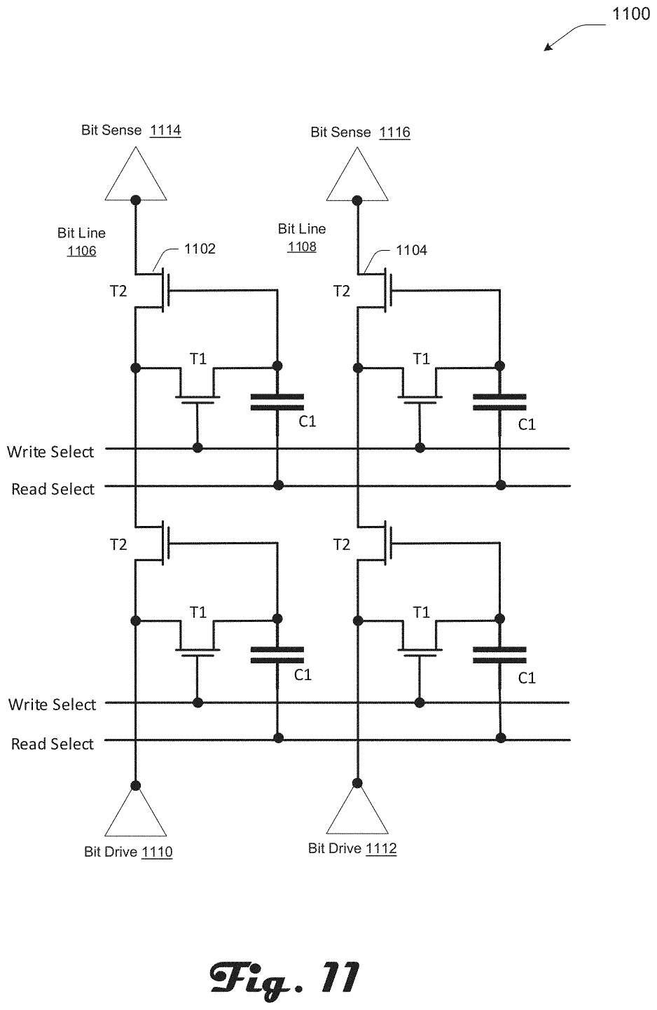

FIG. 10 illustrates an example diagram 1000 of multiple gain cells connected by an output NAND structure in a vertical arrangement. As illustrated, array 1000 incudes a 4×4 arrangement of memory cells 1002, connected via read and write select lines 1004.

It some aspects, larger capacitors may be used, trading off a more relaxed layout in return for more electrons, and thus more bits, per cell.

Of particular interest is the formation of the dielectric, which, in some cases, may cover the full area above the cells, punctuated only by vias. The dielectric may be particularly significant when it is between the capacitor plates. One of those plates may be utilized as the read-select line, with the other plate forming the sense gate of the output transistor, the channel of which passes overhead in the same path as the read-select line. If the dielectric is designed to be ferroelectric, then the materials for the read-select and the sense gates may be chosen to be compatible with, and to aid formation of, the ferroelectric properties of the dielectric. For example, a p-doped germanium layer may be selected to be in contact with hafnium oxide dielectric.

It should be appreciated that various features of the memory devices described above may be combined in various ways. For example, either of circuits 300 or 400 may be implemented in various arrays 500-800, may be formed by according to the stages of FIG. 9, and/or may be formed into device 1000. It should also be appreciated that the layouts and features of arrays 500-800 may be combined in various ways into a single device.

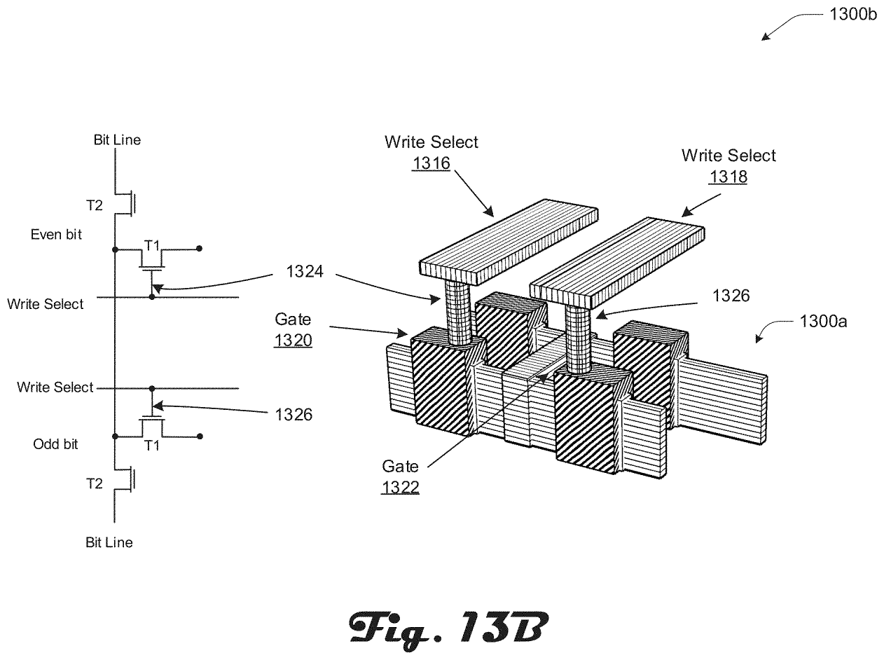

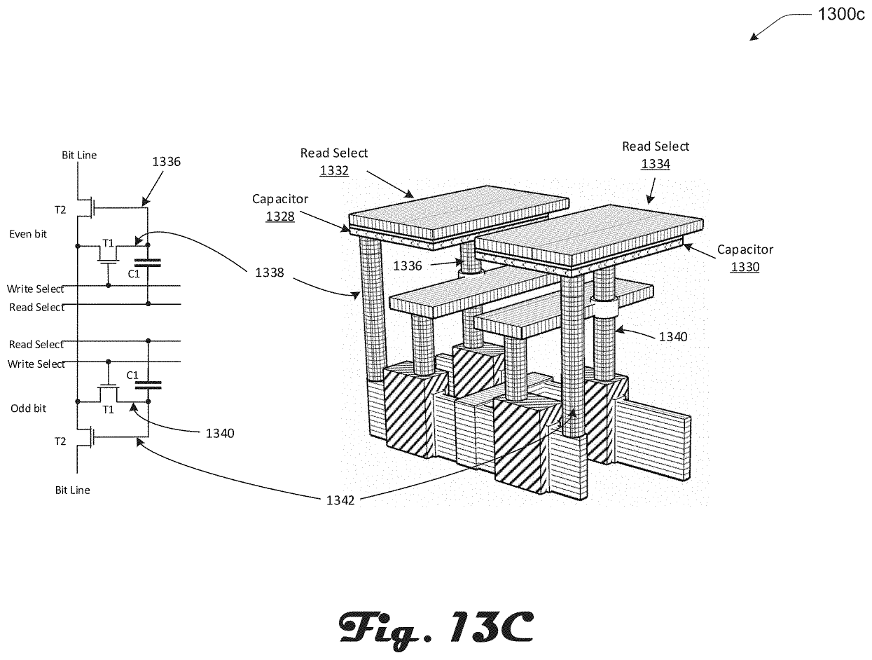

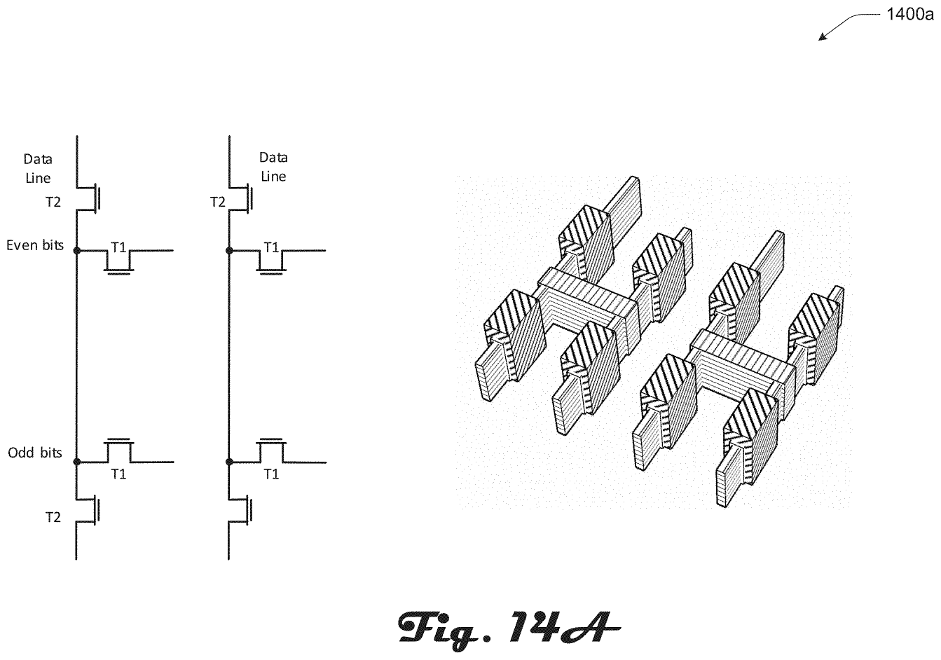

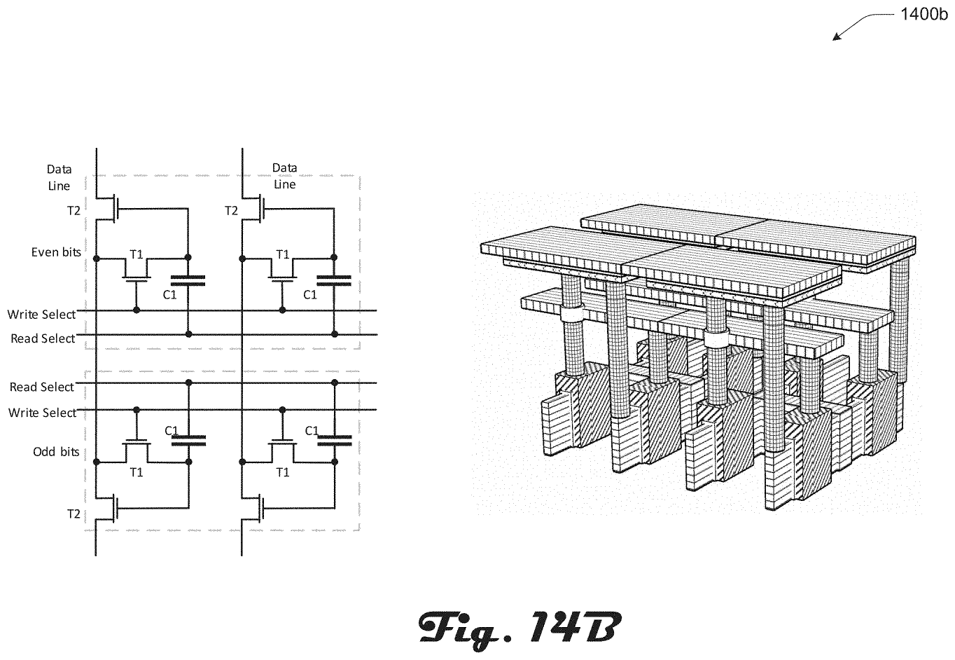

In some aspects, the transformation of the NAND connected output circuit into a compact semiconductor device may be accomplished by utilizing vertical organization to place the writing elements of the cell (e.g., access transistors, data input lines, and write select lines) into different vertical layers than the reading elements of the cell, (e.g., the read select line and the stacked-channel output transistor with the NAND channel), while the capacitor may reside in yet another separate layer. Interconnections between these layers of elements may be formed as vertical conductors (usually referred to as “vias”) between elements to complete the circuits. These cells may be constructed such that the layers connect directly to the same layers of adjacent cells so as to form an orthogonal row and column structure in both the writing layers, and in the reading layers. The shared direction used for the write select and read select lines forms the rows, and the shared direction used for the data input lines and the data output lines, which are the NAND channels, form the columns. Advantageously, these line and row elements can be formed predominantly as linear geometry, with width smaller than length, which continue between cells without interruptions or diversion, and with an overall regularity. This arrangement may enable small features to be most clearly and reliably formed in optical lithography (which include DUV and EUV systems of lithography). Examples of the compactly adjacent designs successfully following these principles are illustrated and described below in reference to FIGS. 13-19.

Another important discovery is that more than one level of output may be constructed in the vertical direction. This allows for larger capacitors to be placed in each layer, along with read select lines for each layer, while fitting within the area budget set by the layer with the writing elements. In some cases, the read select and data output lines will arrive at the edge of the cell array at 1, 2, 4, or more levels and will be routed down to the edge circuitry on the base layer. In some realizations, some of the edge circuitry may be in each layer, such that, for example, the current drive and output buffers may be repeated in each layer.

In some cases, it is also possible to organize the write elements into multiple layers, possibly as immediate neighbors of the output layers. This allows larger transistors to be combined into a smaller overall area, though it will further add to the layers of processing on the wafer.

The use of additional layers allows the areal density of the chips to be optimal, limited by the larger of the layout needed for either the writing elements, the reading elements, or the capacitor. In some cases, advantageous designs may be limited by an ideal unit squares, where the unit square is the minimum reliably resolved feature of the lithography. These designs assume that vias are smaller than this unit square, using physical processes to narrow the channel which is etched and filled below the size of the initial resolved feature. Now, this is at the cost of forming additional layers of active circuitry, multiple distinct processing steps for the wafer. The cost of this may be mitigated by keeping the layers very similar, which minimizes the design complexity and can allow reuse of some masks.

To form these memory arrays, multiple or all of the processing steps can be implemented as a standard CMOS process. This allows dense memory to coexist with other CMOS circuits. Such embedded memory with high data capacity will be an advantage for memory intensive computational chips, such that larger working memory may be located close to the logic, for minimal latency and power.

In some cases, ferroelectric and other new types of dielectric may be used. Several of the design examples described below show layers ordered such that the primary capacitor is formed high in the stack after most harsh process steps would be finished, which maximizes the chance of the material chemistry and crystal structure being reliable after the processing is completed.

FIG. 11 illustrates an example of a NAND output circuit 1100. The NAND output circuit 1100 is transformed in a novel way by unifying the NAND channel 1102 and 1104 with the data (bit) line 1106 and 1108, respectively. A current and voltage are applied to one end of the channel by the bit driver 1110, 1112 so as to pass through the channel where the output transistors may modulate the current and voltage, such that the modulation is measured by the sense amplifier 1114, 1116 when it reaches the other end of the channel. The same bit driver also sends the current and voltage into the unified data line when values are being written. The output transistors are prevented from modulating the incoming level while a write operation is occurring since the read select lines are all held at a default state where the output gates are not at a voltage which inhibits the data value from the bit driver. All the read selects are normally kept in their default state which allows current to flow through T2, while the write selects are normally kept in a default state which blocks current flow through T1.

When a row is to be read, the read select line for that row only is changed an active state. The charge held on C1 is now able to modulate the transistor T2 between conductive and non-conductive, including in some realizations, the use of states in between (e.g., for multi-value gain cell implementations). As all the other T2s are unchanged and conductive, this change in one T2 can be observed by driving one end of the bit line and sensing at the other end.

In some aspects, even though the data line is unified, the read select line of the word being written may be set at a different voltage during writing, a voltage where the output gate may modulate and inhibit current flow. This is especially useful when the cell capacitance is a ferroelectric which requires the cell side of the capacitor to be set to either a positive and negative voltages relative to the read select side of the capacitor, with the positive or negative value reaching a value which will be retained by the ferroelectric material. In this case the output gate thus modulated shall be further distant from the bit drive than the place at which the data line is connected to the access transistor. Thus the word being programmed shall modulate only the data line beyond itself, allowing the unified line to set a value on that word without self interference. The voltage set upon the read select line may in some aspects be the same as the read enable voltage, while in other aspects the read enable voltage may be different.

When a row is being written, all read select lines are in default states such that all T2 are conductive. All the write select lines are inactive, holding all T1 closed, excepting the write select line on which enables the access transistors T1 on the row being written. In that row, T1 is enabled to pass the bit line value through to the interior side of the capacitor C1. At this time, the Read Select value for that row is changed to a value which matches writing, so that the value set on the capacitor will be the value needed to save. When enough time has passed to reach the target charge value on the capacitor, the write select can return to default and transistor T1 closes to trap the charge on C1. In some aspects, it is also possible to activate read select during writing, which allows the output of the sense circuits to be similar to what will be observed in a read operation. This permits feedback for accurate setting of multiple distinct charge levels stored in one cell.

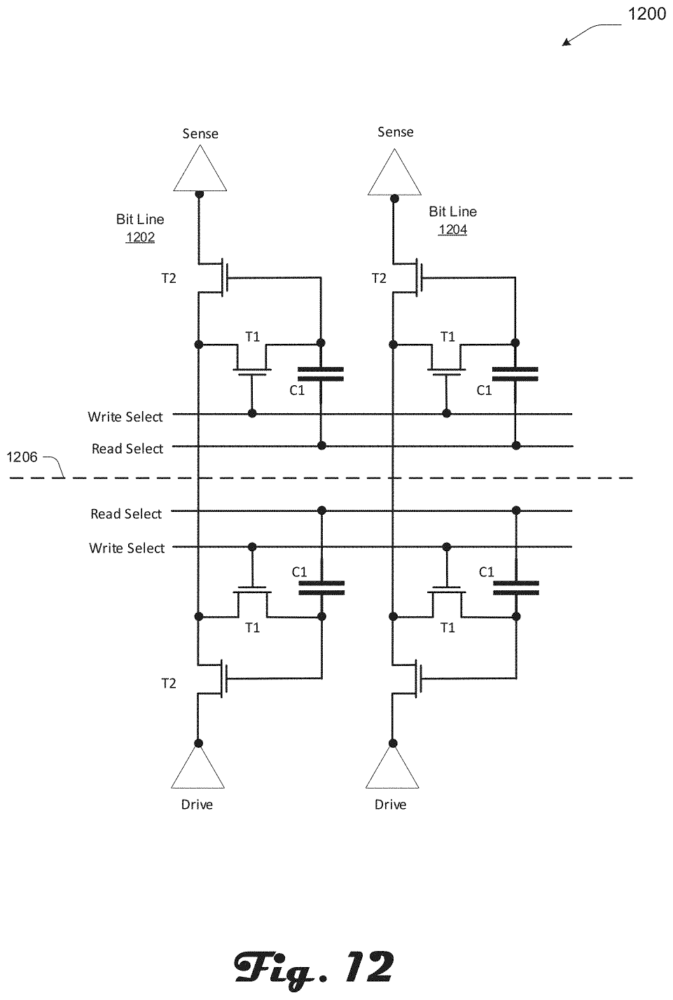

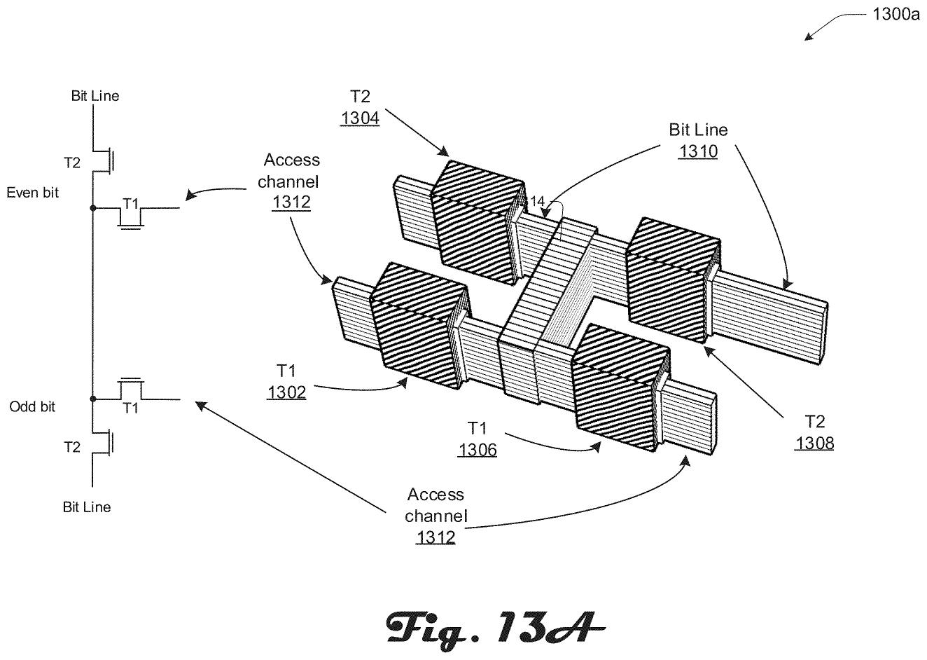

FIG. 12 illustrates another example NAND output circuit 1200. A further innovation on the NAND design uses unified bit lines 1202, 1204 but with a reflected layout (across line 1206) of alternating bits in the same column. This will allow some parts of the cells to be shared, eliminating the size of one copy of those elements and also avoiding needing a separation between every pair in the column.

This NAND output circuit arrangement does complicate simultaneous reading while writing for every second row, since T2 will fall between the value drive and Ti. If precise feedback on charge level is desired, it may be necessary to have driver and sense at both ends, selecting the direction to keep T2 opposite the direction of drive.

Other benefits/tradeoffs between the two forms include the ability to reduce disturbance effects when separate lines are used for the NAND output, and a better use of vertical space especially when 2 or more layers of capacitor and output NAND channels are stacked above the base cells. The use of multiple layers may also simplify the layout of the larger drive and sense circuits, for example by alternating sense amplifiers at opposite ends for each layer.

Various implementations of one of memory circuits 1100 and/or 1200 (either 2 value cells or multi-value gain cells) may include forming the circuits in a number of ways, such as using finFET techniques and other techniques. Examples of these layouts and designs will be described below in reference to FIGS. 13-19. In some examples, these designs may be described in different stages. Individual stages may, in some cases, represent different steps in a formation or manufacturing process of the memory cells, such that they may be in order or relative order. However, other orders and other formation processes are contemplated herein, such that the various stages may be representations of the memory cells, and not indicate actual formation processes, where different stages may be sued to more clearly describe the various structures of the memory cells.

It should be appreciated that these designs are given as examples, and that various medications to these designs and layouts are contemplated herein.

As described and illustrated throughout, elements may be not drawn to scale or exact shapes, so that the illustrations can stay simple and explanatory. Different fin counts may be used for example to create faster cells where 2 or 3 fins are used for each circuit element where more current needs to flow, but single fins are the most compact approach and easiest to explain, so that is what is illustrated.

Semiconductor fins are typically laid out evenly spaced and parallel, which may be achieved with immersion lithography and one or more steps of pitch splitting (LELE, or “litho etch litho etch”) which generates fine linear features such as fins. The fins are supported upon an underlying substrate which will not be shown in the figures for clarity. The fins will likely extend much longer than shown, and there may be many more fins beside these, covering an area of the chip where memory or other circuits will be built using them. The following FIGS. concentrate on a small section which demonstrates how a unit of memory cells may be constructed. The example cells are designed to be repeated in adjacent positions, repeating to fill up an area to create a memory array. The elements of the cell are chosen to align with copies of itself in these adjacent position. Those skilled in the art will recognize that the resulting patterns are chosen to be compatible with lithography and design rules for modern technologies with minimum sizes.

FIG. 13A-13C: illustrate a sequence of stages 1300a, 1300b, 1300c representing in general terms how a reflected-pair circuit, such as circuit 1200 described above, is transformed into physical circuits using FinFET technology.

As illustrated in FIG. 13A, the base elements 1302, 1304, 1306, 1308 correspond to transistors T1 and T2, respectively, and their gates. In the example illustrated, base elements 1302, 1304, 1306, and 1308 are built with fins, such as formed from the high-quality silicon crystal of the base. The fins may be etched and doped to form channels at their top edge, then wrapped with gate insulators and gate electrodes. The bit line 1310 and access channel 1312 are in adjacent fins, with a bridge 1314 connecting them at the center of the access channel 1312, so the access channel 1312 will support a separate bit of storage at each end. It should be appreciated that empty areas may be filled by a material with a low dielectric constant, such as is standard practice, and may not form an active part of the circuit. This is omitted from the figures for clarity.

As illustrated in FIG. 13B, a stage of formation 1300b of a FinFET memory circuit, as described herein, may be a subsequent stage to stage 1300a described above in reference to FIG. 13A. As illustrated, above the base structure 1300a, the write select lines 1316, 1318 may be constructed. Write select lines 1316, 1318 may connect to the access channel gates 1320, 1322, for example using vias 1324, 1326.

As illustrated in FIG. 13C, a stage of formation 1300c of a FinFET memory circuit, as described herein, may be a subsequent stage to stage 1300b described above in reference to FIG. 13B. As illustrated, capacitors 1328, 1330 and read select lines 1332, 1334 may be formed/placed above the base elements, such as those elements formed and discussed above in reference to circuits 1300a and 1300b of FIGS. 13A and 13B. In this example, the capacitors 1328, 1330 are simple planar capacitors, which may enable high performance ferro-electric dielectrics to be used. However, in other aspects, other types of capacitors may be used. One electrode of each capacitor 1328, 1330 connects both to the access channel, and to the corresponding output gate, for example using vias 1336, 1338, and 1340, 1342 respectively to form the connection. The other electrode of the capacitor is part of or connected to the read select lines 1332, 1334.

FIGS. 13A-13C illustrate the main active elements of a pair of bit cells joined at the middle in a reflective layout which minimizes cell size by sharing some of the access channel and connection paths, and by eliminating the need for a gap to separate those two cells.

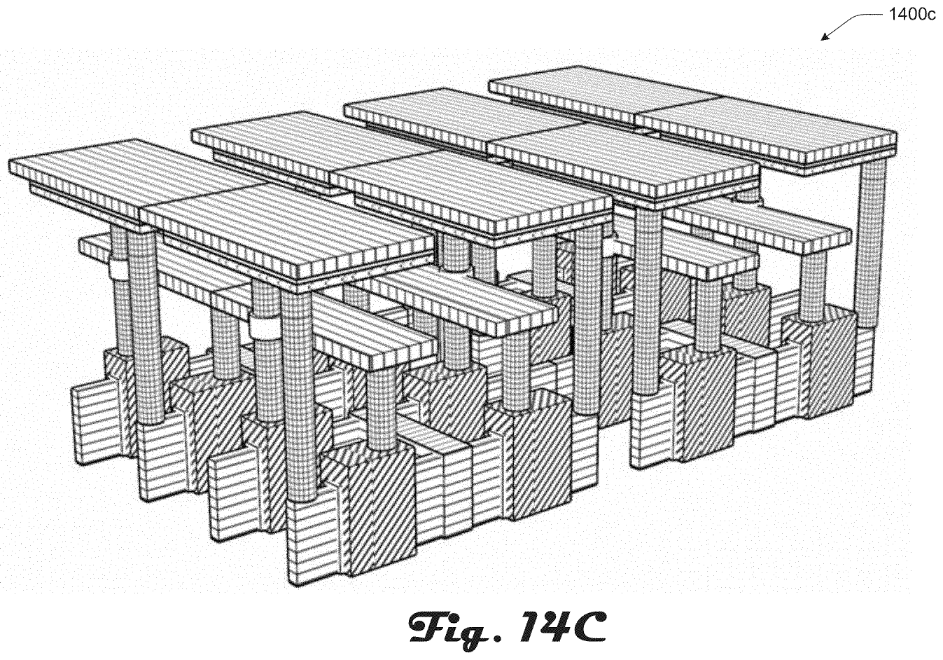

FIGS. 14A-14C illustrate stages 1400a, 1400b, and 1400c of formation or manufacture for creating a layout of memory cells designed for efficient adjacent fabrication to make an array. Stages 1400a, 1400b, 1400c may include one or more aspects of stages 1300a, 1300b, and 1300c described above in reference to FIGS. 13A-13C, and for the sake of brevity will not be repeated again here. As illustrated, two pairs of memory cells side by side show how a row may be formed. The memory circuit formed via stages 1400a, 1400b, 1400c may be an extension of stages 1300a, 1300b, 1300c described above, with four cells instead of two, to illustrate an example relationship between the memory cells when implemented using finFET manufacturing techniques.

First, in stage 1400a, the base is formed with regular vertical and horizontal patterns suitable for modern lithography. Next, in stages 1400b and 1400c, the vias, select lines, and capacitors are added above the base. It should be appreciated that the continuation in the column direction may also be regular or symmetric, with the bit-line being continuous in each column. The design of FIGS. 14A-14C may be extended to larger arrays, with more columns and more rows, limited only by the quality of the materials to pass signals through within desired time limits and signal to noise ratios.

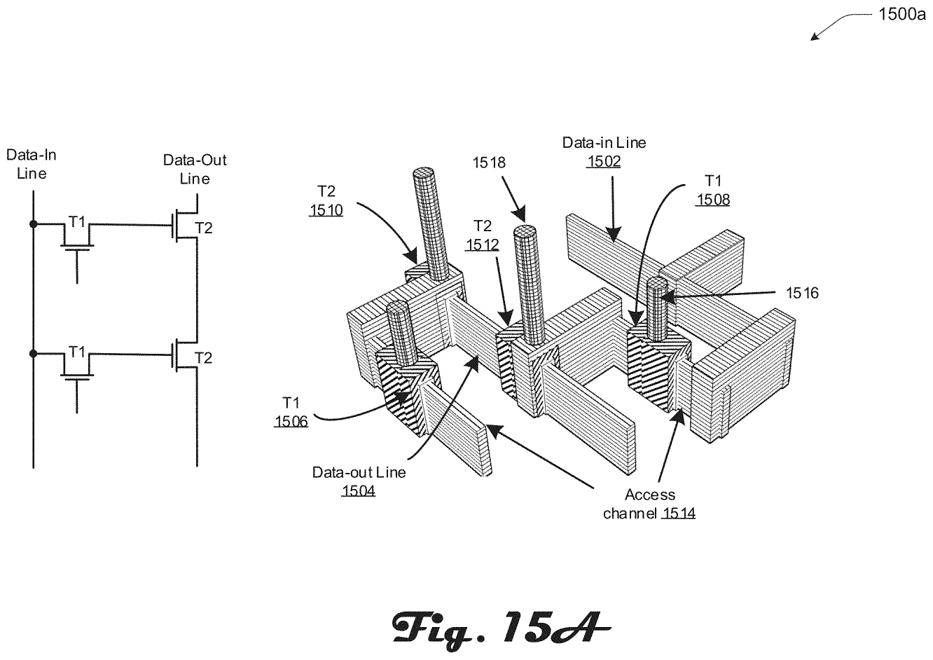

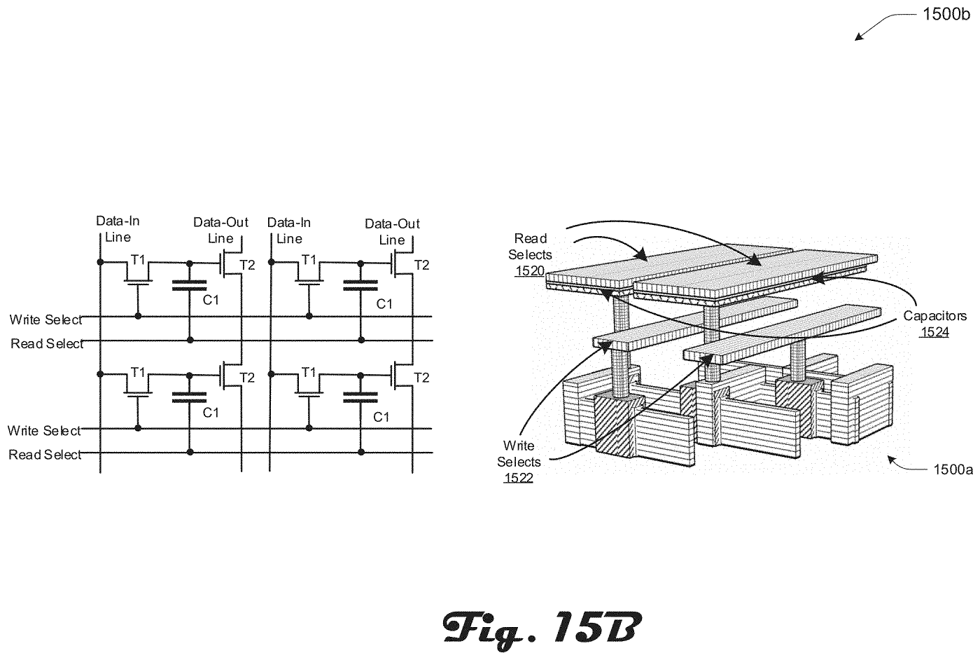

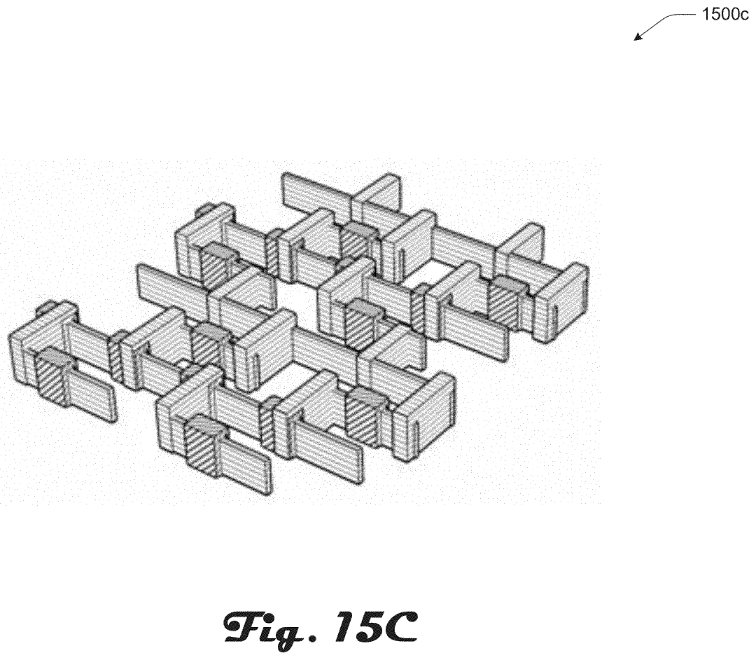

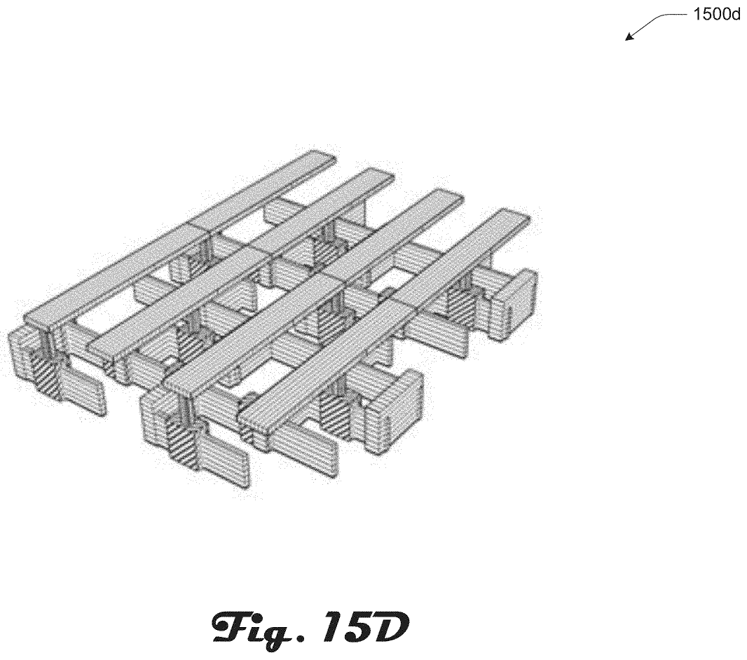

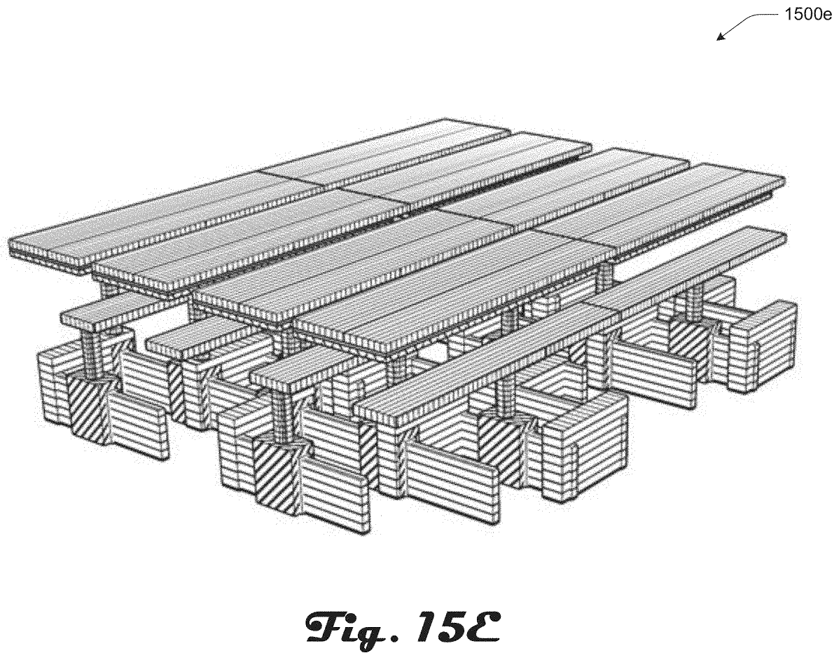

FIGS. 15A-15B illustrate stages 1500a and 1500b, of the formation or manufacture of a layout of memory cells designed for efficient adjacent fabrication to make an array. In some cases, it may be that for some sizes of array, and other reasons including performance and device optimization, that separate fins are preferred for the formation of data-in and for data-out lines. Stage 1500a of FIG. 15A illustrates an example first stage of this type of design, using a FinFET base. As illustrated, data-in line 1502 and data-out line 1504 are formed/located on different fins, with transistors T2 1510 and 1512 located on the data-out line 1504. Transistors T1 1506 and 1508, and access channels 1514 may be formed on fins in between fins for the data-in and data-out lines 1502, 1504, respectively. Vias 1516, 1518 may be formed on top of bridges and T1 1506, 1508 to connect upper layers.

As illustrated in FIG. 15B, a stage of formation 1500b of a FinFET memory circuit, as described herein, may be a subsequent stage to stage 1500a described above in reference to FIG. 15A. As illustrated, above the base structure 1500a, the write select lines 1522, 1318 may be constructed, along with the read select lines 1520 and capacitors 1524 connected by vias, such as vias 1516, and 1518 of FIG. 15A, such as, for example, in a similar way as described above in reference to FIGS. 13A-13C.

As illustrated in FIGS. 15C, 15D, and 15E a memory circuit may be constructed in stages 1500c, 1500d, and 1500e by linking multiple smaller cells, such as those formed by stages 1500a and 1500b described above. For example, smaller cells may be laid out adjacently to form an array of many cells, up to the limits of signal attenuation and required capacity and performance. Stage 1500c of FIG. 15C includes a base with fin and gate layout for adjacent cells aligned to form an array, in a pattern which may be continued, as may be an extension of stage 1500a described above with similar elements. Stage 1500d of FIG. 15D may add control lines to stage 1500c. Stage 1500e of FIG. 15E may finish the memory cell by adding capacitors and read control lines.

While FinFETs are the basic pattern in modern logic processes, a different “saddle cell” approach is widely used in DRAMs. The base units for these use a buried access channel set at a diagonal relative to a grid defined by select lines and bit lines, with vias leading up to the capacitors above. This general plan for a base can be adapted and used as a starting point also for NAND connected gain cells. Both unified bit line form, and forms with separate output lines may be used.

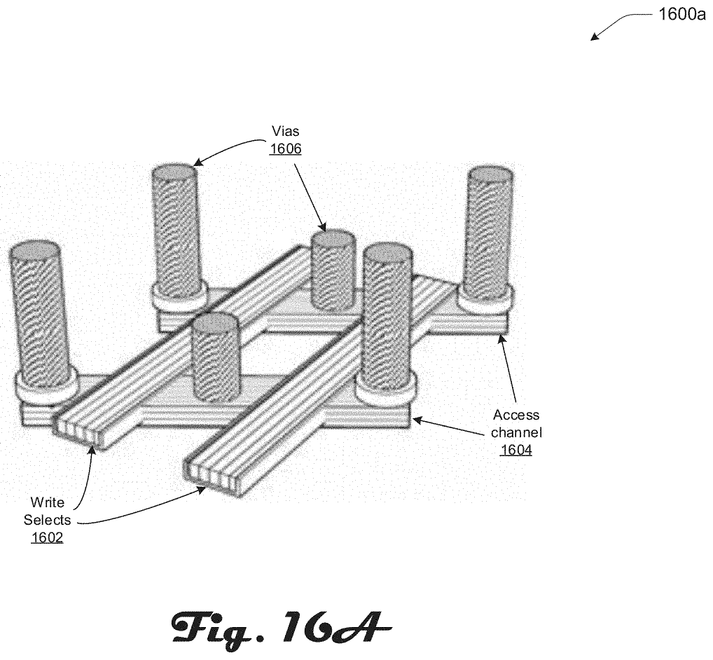

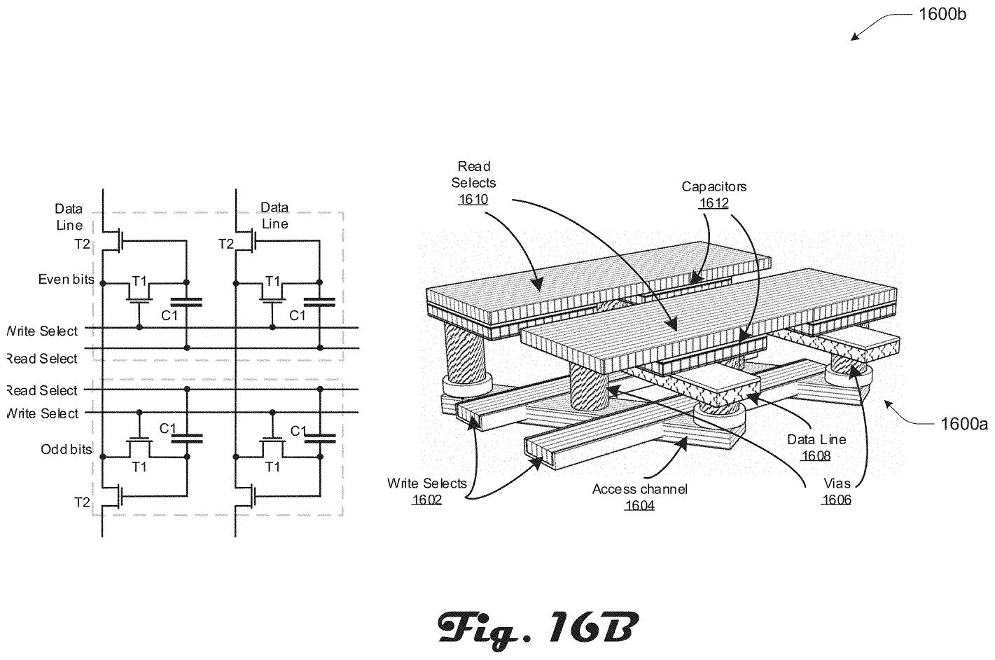

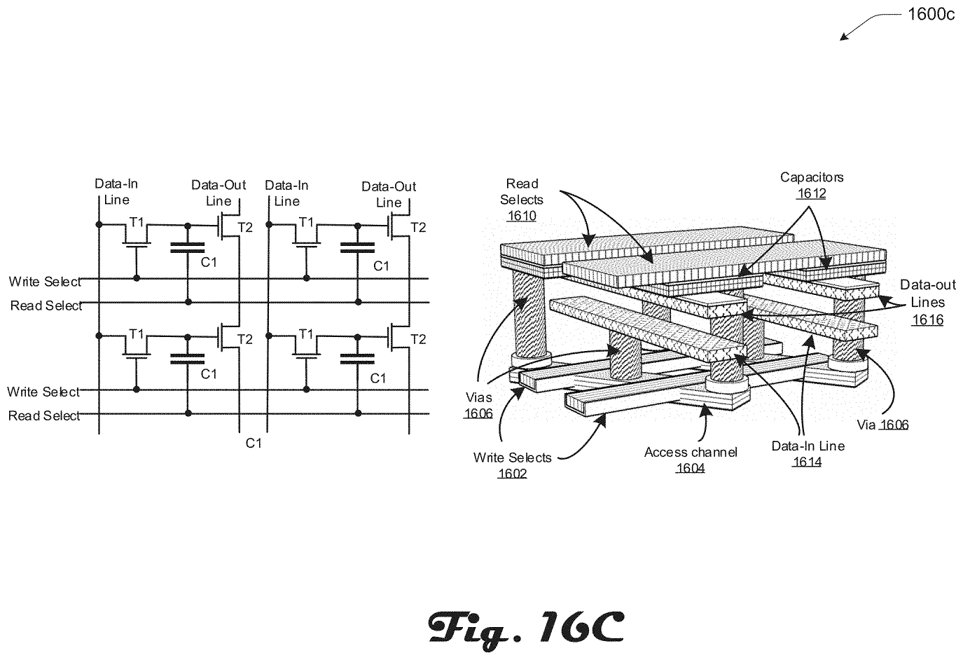

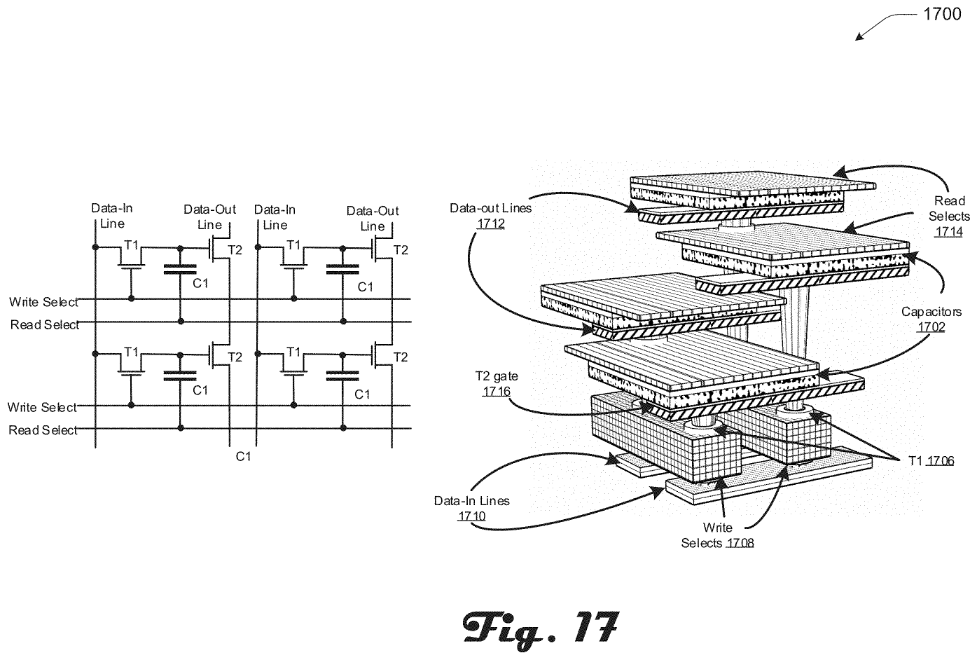

FIGS. 16A-16C illustrate an example stages 1600a, 1600b, 1600c of the formation of a saddle cell memory cell using a NAND output circuit, as described herein. Stage 1600a may include write select lines 1602 crossing and at an angle (e.g., other than 90 degrees) to access channels 1604. Vias 1606 may be formed on and above the access channels 1604 to connect to other elements.

As illustrated in FIG. 16B, a stage of formation 1600b of a saddle cell memory circuit, as described herein, may be a subsequent stage to stage 1600a described above in reference to FIG. 16A. As illustrated, above the base structure 1600a, the data lines 1608 may be constructed and connected to the base structure by vias 1606. Read select lines 1610 and capacitors 1612 may then be connected above, by vias 1606 as, for example, in a similar way as described above in reference to FIGS. 13A-13C. Stage 1600b implements a unified bit line approach. It should be appreciated that similar structures may be used to form separate bit lines, as described above in reference to FIGS. 15A-15E.

As an alternative to stage 1600b of FIG. 16B, stage 1600c of a saddle cell memory circuit, as described herein, may be a subsequent stage to stage 1600a described above in reference to FIG. 16A. In some cases, unification of bit line and NAND channel is not always advantageous. As illustrated, in stage 1600c, in some cases, the NAND channel for the data-out line 161 could be implemented in an upper layer, keeping the horizontal density of DRAM while using the third dimension as a place to construct the NAND channel. This can reduce disturbance, allow materials to be optimized, and simplify the connection of sense and drive circuits at the end of the bit lines 1614, 1616.

In another example design 1700, as illustrated in FIG. 17, a high density process may be utilized to construct a memory cell, based on buried bit lines and vertical gate-all-around access transistors. Memory cell 1700 may be formed using the same circuit with separate data input and output lines 1710, 1712, but could use vertical space to put larger capacitors per bit above the small base unit. In this example, 4 layers are used, each with a 1-bit capacitor 1702 and output line 1704 and T2 gates 1716 forming the NAND structure, above a base unit with four transistors 1706, such as gate all around (GAA) access transistors, embedded inside the write control lines 1708, 1714. It should be appreciated that other numbers of layers and other arrangements, such as different circuit elements and the like, are contemplated herein.

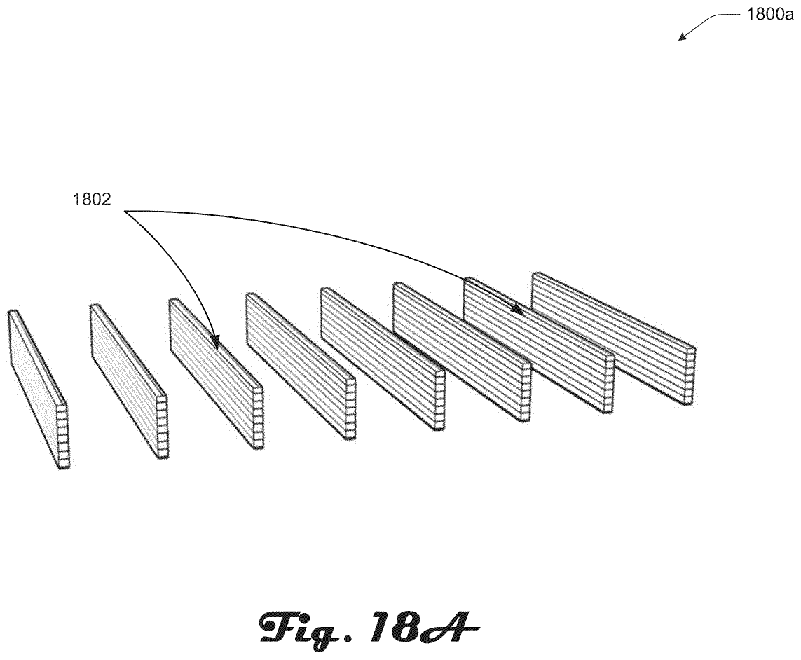

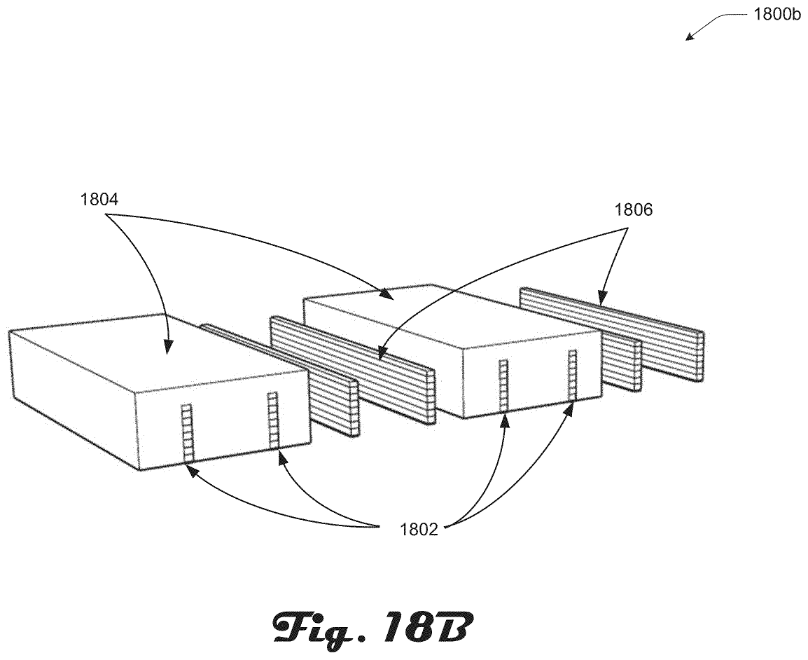

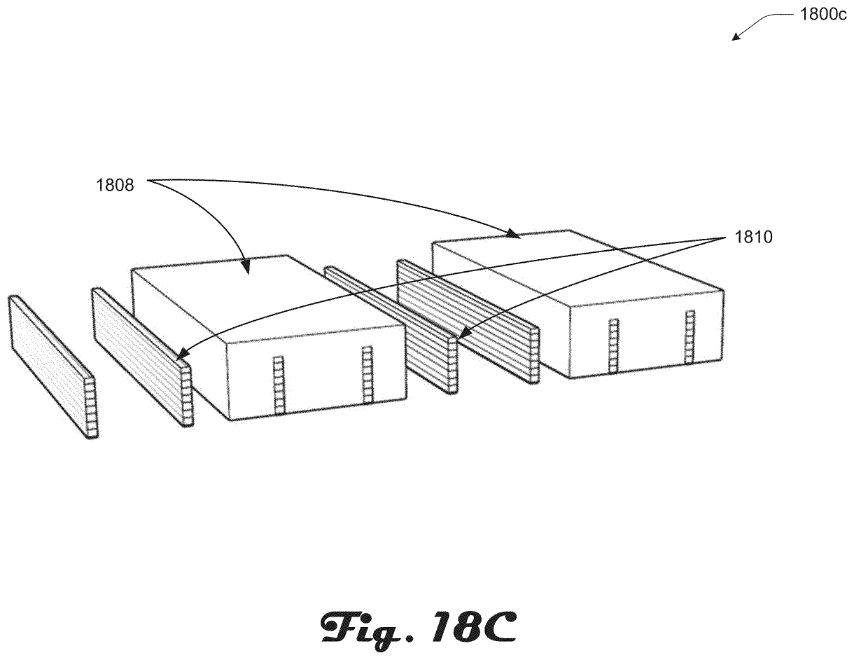

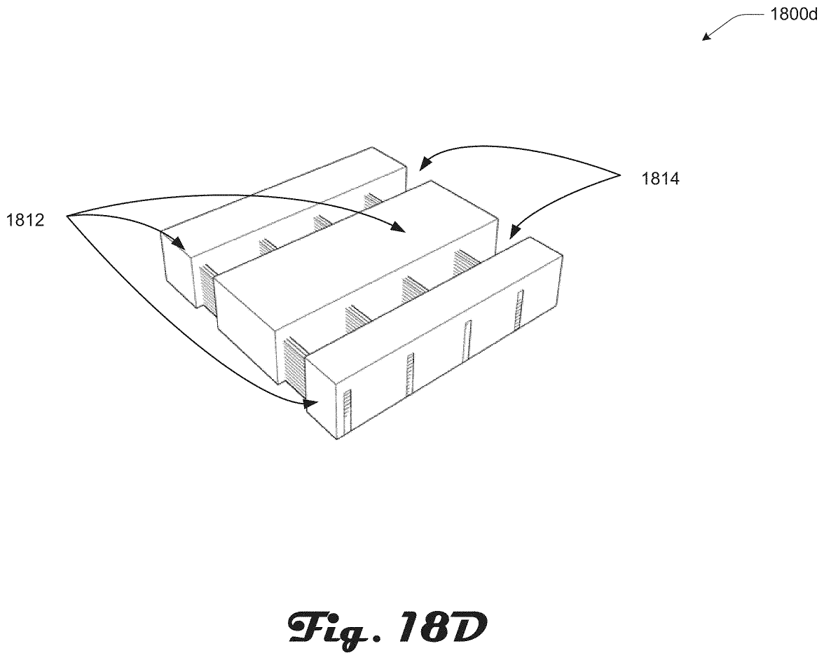

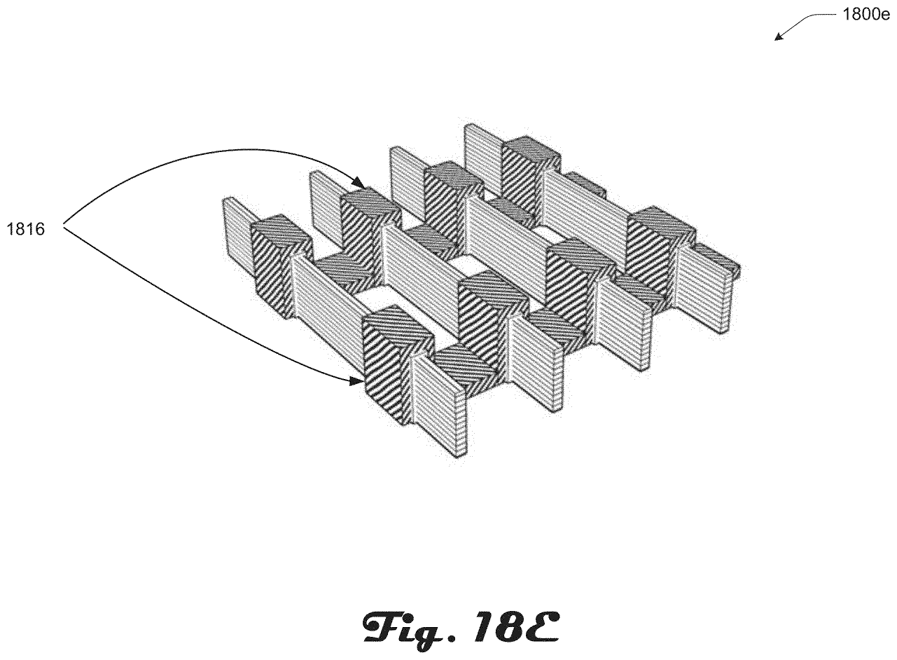

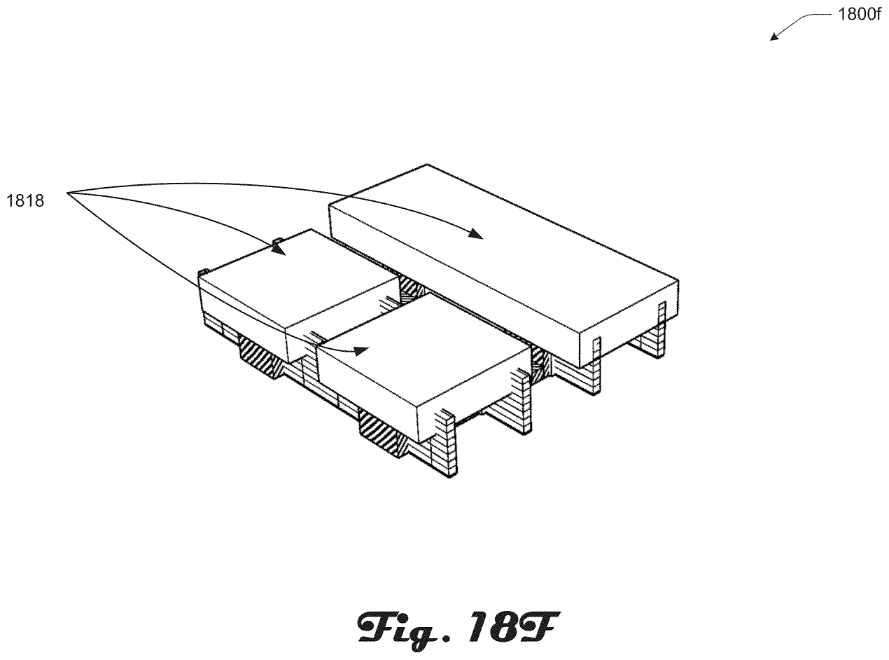

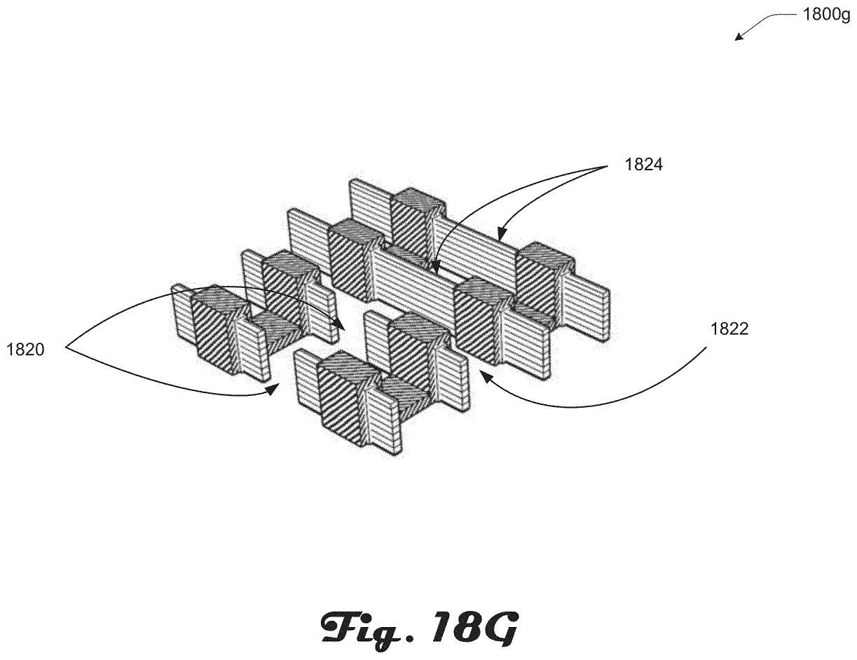

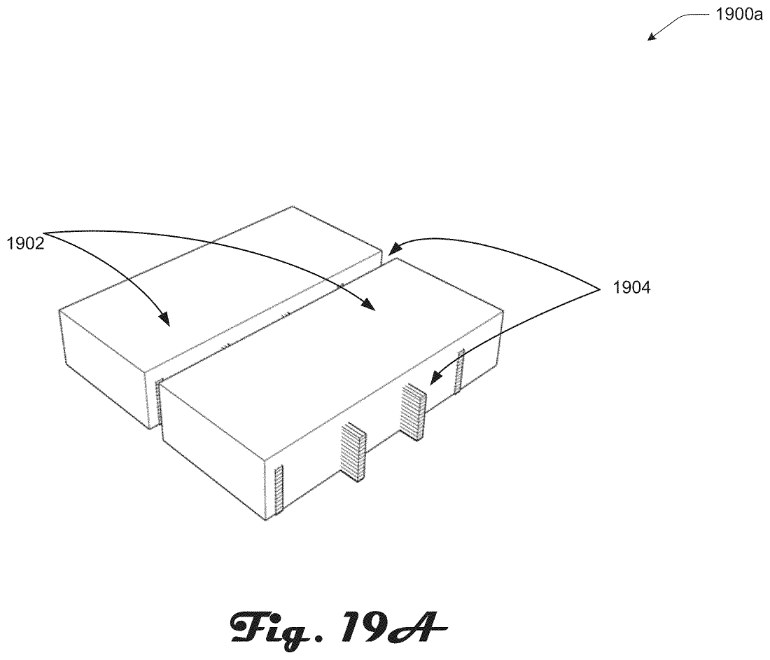

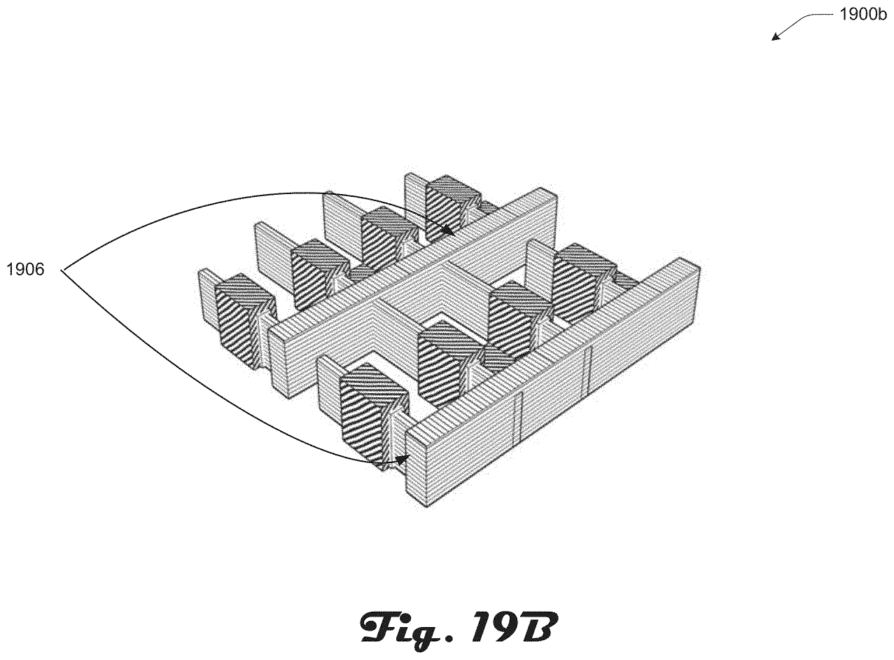

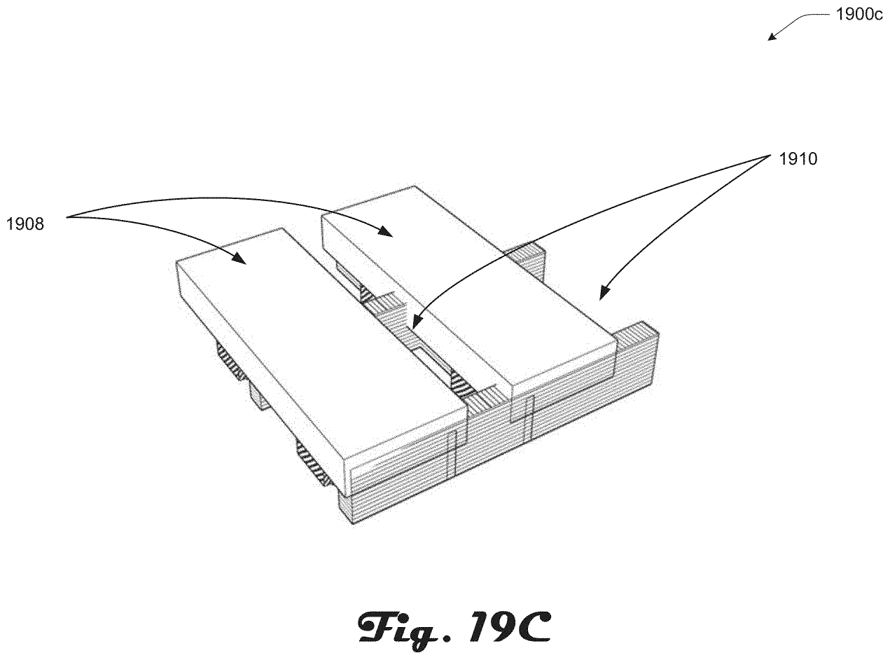

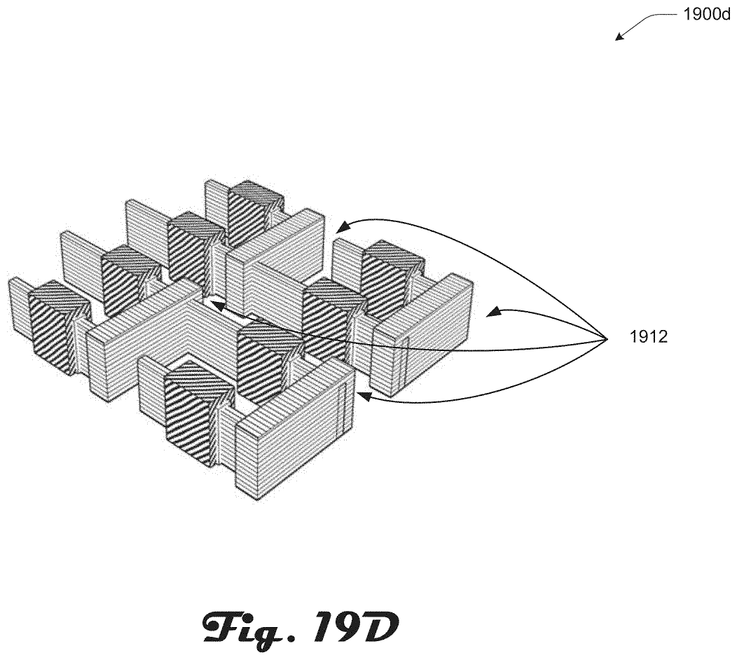

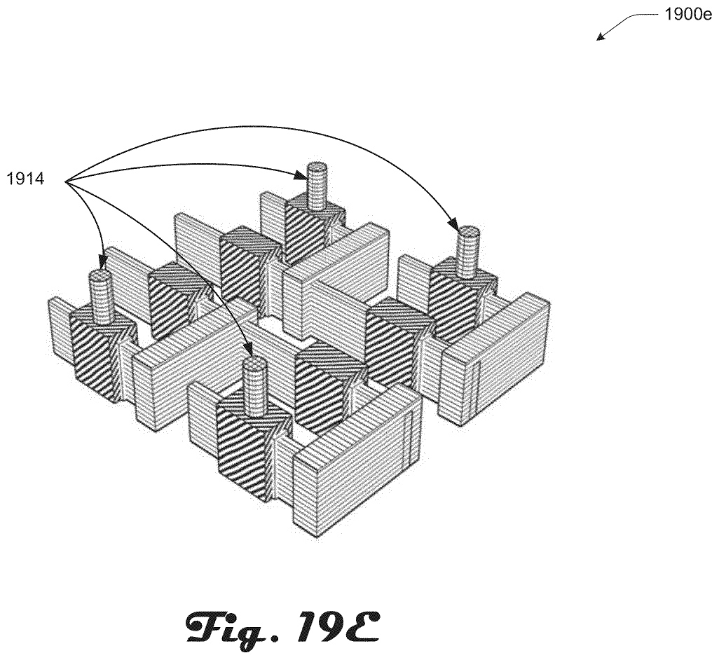

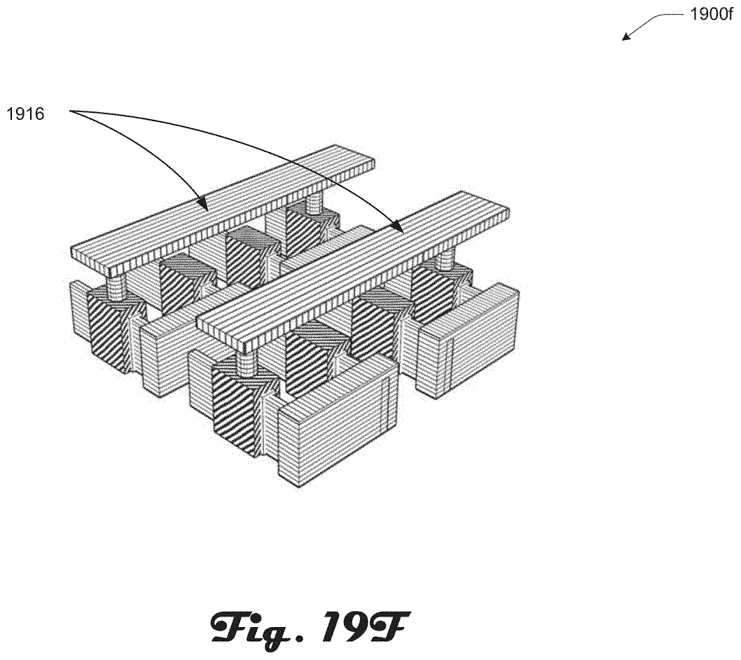

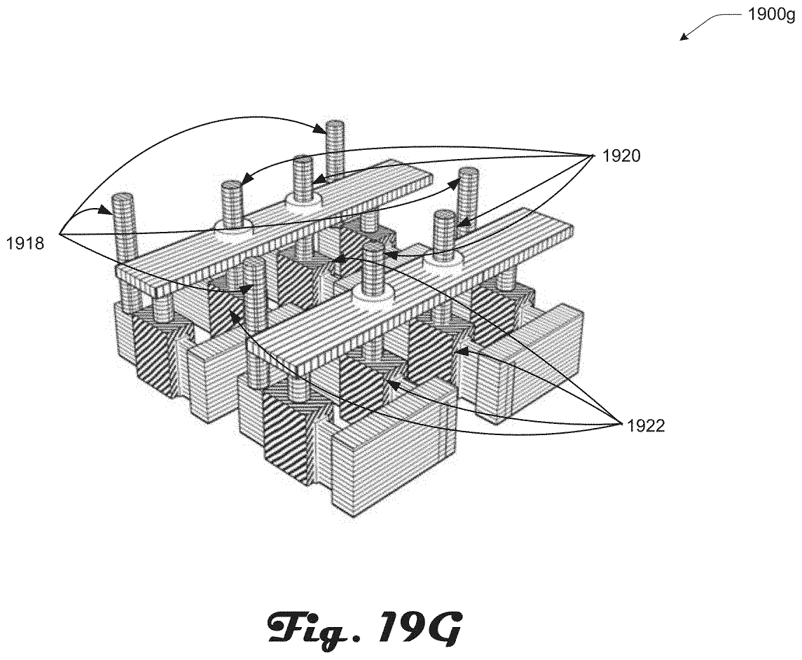

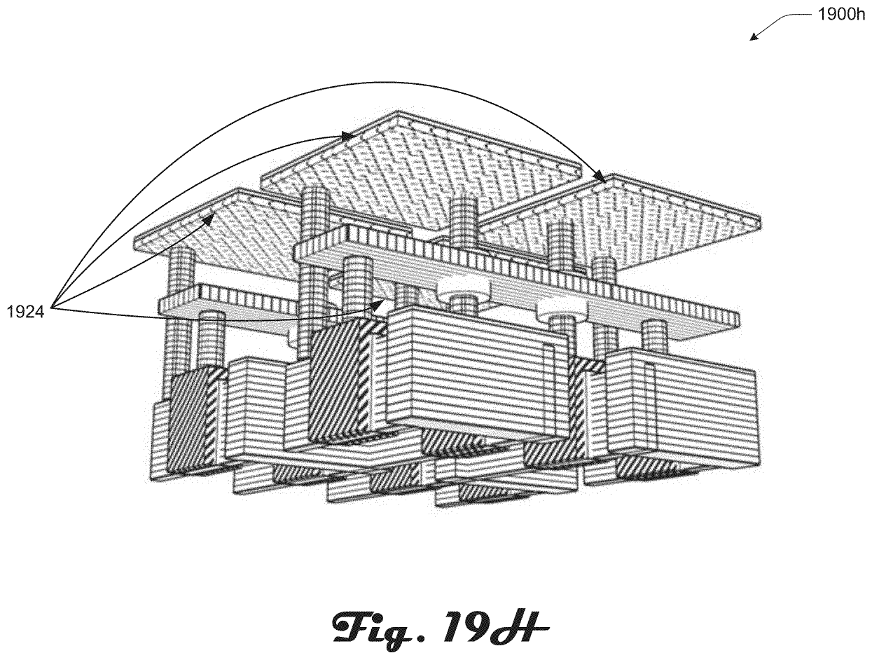

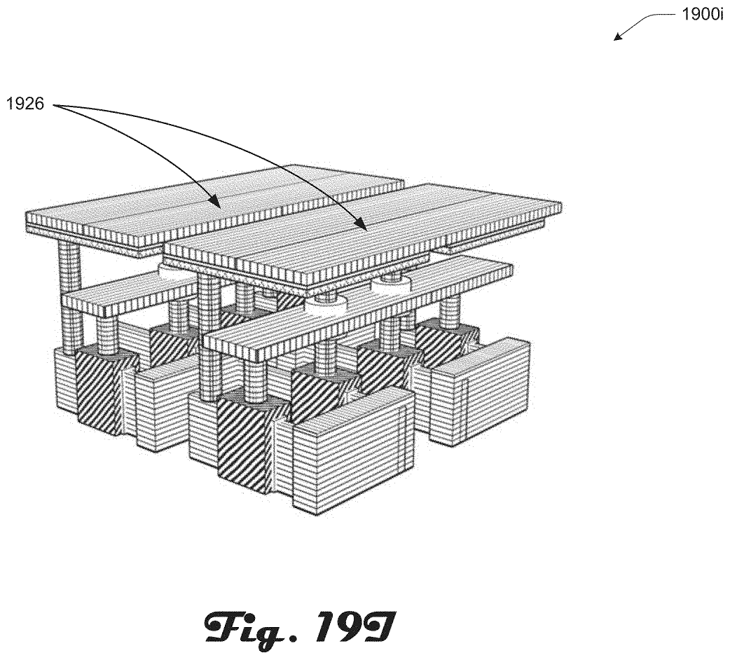

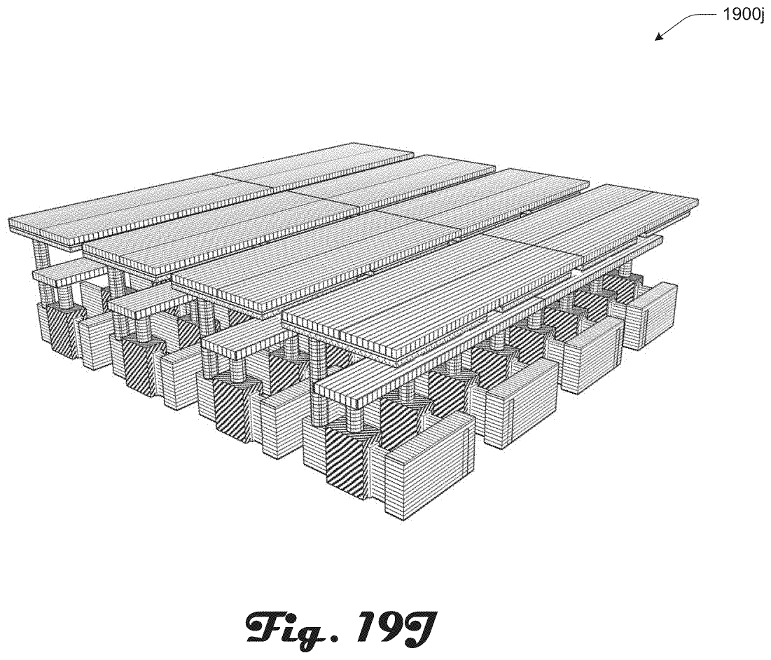

In other example, stages 1800a-1800g, as illustrated in FIGS. 18A-18G, and stages 1900a-1900j, as illustrated in FIGS. 19A-19J, represent another example of a different steps in a process for forming a memory cell, as described herein.

In stage 1800a, of FIG. 18A, fins 1802 in their initial form have been created. Typically, fins 1802 will extend linearly over the full length of a column of the intended memory array, and there will be additional fins to the sides which fill out the width of a row of the intended memory array. Stage 1800a represents a short sub-section, to demonstrate treatments applied uniformly to result in an array of cells with the same design.

Stage 1800b of FIG. 18B illustrates alternate pairs of fins 1802 enclosed in a protective mask 1804. The remaining pairs of fins 1806 are outside of the mask where they are exposed for actions such as doping by ion implantation from above.

In stage 1800c of FIG. 18C, the first doping mask 1804 has been removed then a new mask 1808 is added to protect the fins which already have been doped. The remaining fins 1810 are now treated with a second form of doping. In some cases, there will now be one set of fins doped for free electrons (N-type) and the others doped for excess holes (missing electrons, P-type). Usually P fins will be best for access channels and N fins will perform better as data lines.

In stage 1800d of FIG. 18D, masks 1808 are removed and new masks 1812 added to expose strips 1814 across all the fins. In stage 1800e of FIG. 18E, the mask 1812 has been removed so the gates 1816 formed within those strips are revealed, possibly including excess silicon between gates which will be removed. If the technology or specific implementation requires different gate construction for differently doped fins, then more steps may be or stages may be added here to form 2 different kinds of gate.

In stage 1800f of FIG. 18F, a new mask 1818 has been added that outlines limits for the access channels and will isolate the access gates. The etching through the mask 1818 splits the access gate into one section per cell, and separates the access gate from other gates. In stage 1800g of FIG. 18G, the mask 1818 has been removed and the shorter access gate fins 1820 can be seen, with their gates disconnected 1822 from the fins 1824 which will be the data lines.

As described in reference to FIGS. 18A-18G, the fins have been grouped to match up with the masks. Dual-wide masks are easier to form. The remaining FIGS. 19A-19J will shift over to masks formed on single fin, because the data fins will form the back-to-back center for two pairs of cells, while the fins that are now cut into sections will become the access channels on either side of the data line fins.

In stage 1900a of FIG. 19A, the next mask 1902 allows a connection to be deposited, and optionally doping to be implanted, in the open area 1904 across all the fins In stage 1900b of FIG. 19B, the mask is removed leaving a bridge 1906 which will connect the data fin to the access fin sections. In stage 1900c of FIG. 19C another mask 1908 allows the separation of cells by etching 1910 between pairs of data lines and between pairs of access lines.

At this point a passivation such as SiO2 would fill part way up the sides, the remaining work is done near the tops of the fins. The passivation is not shown in these diagrams, to allow active elements to be more clearly illustrated. The data line fin and access channel fin are bridged together, which finishes the base layer and fin work. Also, at some stage, the chip will be prepared for contacts on the fins, a process not shown since the details are not specific to this circuit, but typically involves adding conductive cladding over the parts of the fins where vias will make contact.

As illustrated in stage 1900d of FIG. 19D, four cells are in groups of two which are mirror images of each other, and they have been separated at 1912 by etching down to the substrate. The groups of two share some elements and reduce spacing, for a more compact layout. The mirror images have ensured pairs of fins can be treated the same way at each step, for simpler masks and process.

In stage 1900e of FIG. 19E, vias 1914 are added which will connect the access gates to the word write enable lines. In stage 1900f of FIG. 19F, the conductors for the word write access lines 1916 are added. In stage 1900g of FIG. 19G, a set of vias 1918 reaches up to the cell side of the capacitors from the ends of the access channels. The output gates 1922 on the data lines are also connected by vias 1920 which will reach the cell side of the capacitor. In stage 1900h of FIG. 1911, the capacitors 1924 are added, connecting to those vias 1918 and 1920.

In stage 1900i of FIG. 191, word read enable lines 1926 may be laid across the top side of the capacitors. There are four capacitors in that block, so this shows a unit of four storage cells. In stage 1900j of FIG. 19J, it can be seen these four-cell formations fit adjacent to each other to fill out an array. All these steps may be carried out in parallel to fabricate the memory array.

It may be appreciated that this array has no need of buried power or other complexity underneath the cell array. Power and current to put charge into the capacitors will come from a bit driver at one end of the data fin, the output of which is sensed after passing through the rows at the other end of the data fin. The word write select line and the word read select lines are also driven by circuits at the edge of the array.

In some aspect, the described system and techniques may include one or more of the following features. It should be appreciated that various combinations of these features are completed herein, and that language indicating a particular inclusion of a combination of features is not a requirement that those features operation in combination to provide one or more advantages as described herein.

(1). In one example, a dynamic memory cell may include or utilize one or more of the following: a selectable access FET transistor (T1) connected on its channel to a data input line and controlled by a word input select line on its gate and having a low leakage through the channel when the gate is not selected; one or several capacitive elements together acting as a capacitor C1 connected to the channel of T1 at the opposite end from the data input line so that T1 controls current flow between the data input line and C1. The side of C1 which is connected to T1 is called the cell side; a write select line which modulates the access transistors T1 in a row, holding them non-conductive by default so that the charge on C1 does not change substantially; a read-select line connected to the opposite side of parts of capacitor C1, called the select side of C1, such that when the voltage on the select line changes it will control the voltage on the select side of C1; an FET sense transistor T2 where the gate is connected to the cell side of C1, and the gate capacitance is an element of C1, so that the charge stored in C1 and the voltage on the cell side of C1 will control the gate voltage of T2, where the Sense transistor T2 is constructed in newly deposited layers above the base level of the chip separated from the chip by insulating material and connected to the chip below by metallic vias, where the transistors T2 of a set of adjacent cells shall be connected such that their channel is continuous and formed in the layers deposited above the chip where T1 was fabricated, and each has their gate on that channel so that the sense transistors T2 of the adjacent cells form a stacked-gate multiple-stage transistor, also known as a NAND transistor. The set of adjacent cells with gates on a shared channel NAND shall be referred to as a NAND string of cells; and a read string select line is connected to one end, the power end, of the channel of the NAND transistor to provide current and voltage so that the transistor may generate a signal. The NAND channel is composed with dopant materials such that it is normally conductive, including parts of the channel not under the T2 gates, where the T2 transistors in their default state permit the channel to be conductive, such that the T2 transistors operate by preventing current flow when the transistor is activated by the correct gate voltage, and where the opposite end, the output end, of the channel of the NAND transistor is connected directly or indirectly to sensing circuits which will detect and amplify the data-output.

The elements of (1), where the cell capacitor C1 is formed in the region above the base chip and the cell side of the capacitor also the gate conductor element for sense transistor T2.

The elements of (1), where a Read Select line forms the side of the cell capacitor C1 opposite to the cell, such that the voltage on the cell side including the voltage applied to the gate of the sense transistor T2 is modulated by the voltage of the Read Select line and the charge trapped in the cell.

The elements of (1), where read select lines default when not selected to a voltage such that the modulation of voltage at the sense transistor gate shall allow the channel of the sense transistor T2 to be conductive, no matter what charge is stored in the capacitor C1. Only one Read Select line is changed to an active voltage for the purpose of reading data. The active voltage used will distinguish between the levels of charge trapped in the capacitor C1 such that one charge state shall allow the output transistor T2 to remain conductive while a second charge state shall cause the output transistor to inhibit current flow.

The elements of (1), where the read select lines are all in default state while a write operation is in progress.

The elements of (1), where any one of the read select lines may be active during Writing, allowing independent reads and writes to proceed simultaneously or with overlapped timing.

The elements of (1), where both write select and read select of the same row may be activated at the same time so that the level of charge being written may be monitored as it is written for purposes of feedback or reliability.

The elements of (1), where the additional elements for T2 and the data output line and the read-select line are formed from additional elements of semiconductor, insulator, and conductors which are built substantially above the mechanisms of T1 and C1.

The elements of (1), where a read operation on one stripe of words shall be able to run at the same time as a simple write operation (17) and a read operation (18) where the write is on one stripe of words while the reader is on a different stripe of words, such that the two stripes have no cells in common.

The elements of (1), where a simple write operation is combined with a read operation on the same word of cells, so that the cell is being read while it is being written, allowing a write with feedback to the input driver circuits so that the value written may be accurately adjusted even in the presence of variations in cells and circuits.

The elements of (1), where an encoder and digital to analog conversion circuit will supply the ideal voltage on one or several cells which will represent the bits of the digital value to be written into each cell.

The elements of (1), where each cell shall be activated for reading at the same time as activated for writing and a differential amplifier shall use negative feedback from the read value to drive the data input to each cell through its active access transistor T1 to set the accurate charge level on C1 which is tracked by activated T2 and reported out on the data output line which is connected to the negative feedback of the amplifier. This feedback loop shall be designed to avoid oscillation and properly converge to matching the ideal reported read voltage desired for each cell.

(2). In another example, a dynamic memory cell in gain configuration with two transistors T1 and T2 where a single semiconductor element serves both as the data input and as the channel for the stacked output transistors T2 in a NAND configuration, may include: a selectable access FET transistor (T1) connected on its channel to a data input line and controlled by a word input select line on its gate and having a low leakage through the channel when the gate is not selected and the word input select line is in its default state; one or several capacitive elements together acting as a capacitor C1 connected to the channel of T1 at the opposite end from the data input line so that T1 controls current flow between the data input line and C1. The side of C1 which is connected to T1 is called the cell side; a read-select line connected to the opposite side of parts of capacitor C1, called the select side of C1, such that when the voltage on the select line changes it will control the voltage on the select side of C1; an FET sense transistor T2 providing gain on output where the gate is connected to the cell side of C1, and the gate capacitance is an element of C1, so that the charge stored in C1 and the voltage on the cell side of C1 will control the gate voltage of T2, where the channel modulated by the gate of T2 is formed upon the semiconducting channel of the input line so that it shall modulate it to also function as the output line, where the output transistors T2 of adjacent cells use this input data line as the channel of a stacked-gate multiple-stage transistor, also known as a NAND transistor, and where when the Read Select is in default state T2 shall allow current to pass through the channel, both for input and for output, regardless of the charge stored on the capacitor C1, where when Read Select is at its Active voltage the charge on C1 shall modulate T2 between conduction and blocking of the data line, whether for input or for output; and a read string select line is connected to one end, the power end, of the channel of the NAND transistors to provide power so that the transistors may modulate this signal according to the voltage stored in each cell, where this drive shall also provide the signal level when writing a value into a cell, through the active access transistor T1 of a write-selected row, and where the opposite end, the output end, of the channel of the NAND transistors is connected directly or indirectly to a sensing circuit.

The elements of (2), where the capacitor C1 may hold any of multiple different charge levels, representing 1 or more bits of information.

The elements of (2), where a write operation is done by: activating the write select line for just one word while all other write selects are held at a default inactive state, which enables Ti in each cell attached to that write select line to become conductive so that the cell side of capacitor C1 is connected to the data input line; presenting upon the data input lines which intersect the cells of the enabled word on each data input the individual voltage levels which will set the desired charge into each cell; allowing enough time for the charge levels to settle within desired accuracy; and inactivating the write select line for these cells so that Ti in each cell shall be non-conductive to preserve the charge inside C1 substantially constant for a useful period of time.

The elements of (2), where a read operation is done by the following steps, which may be reordered so that this is just one possible functional ordering: the default state of read-selects is fully inactive, where the fully inactive level is a voltage such that no charge differential on C1 shall cause the gate of T2 to be active, and where the NAND transistor T2 is fully conductive when inactive; the bit line drivers are enabled to set a voltage and supply current into the bit columns of the data bits to be read; and for the word being read, the read-select line is changed to a voltage where the level of charge stored in the cell capacitor C1 will result in a voltage at the gate of sense transistor T2 such that the channel of the NAND at T2 is modulate with a value transferred through the NAND channel to the sense circuit at the end of the bit line.

The elements of (2), where a read operation on one row of cells shall be able to run at the same time as a write operation on a different row of cells.

The elements of (2), where a read operation on one row of cells shall be able to run at the same time as a write operation on the same row of cells, allowing a the operation to be monitored at the sense amplifiers for purpose of feedback on accurate level setting, or for purposes of quality control.

(3). The elements of (2), formed in an array with extra columns of cells used as reference values, where there may be 1, 2, or more standard reference values in use, each for a different reference column, so that accurate inferences about the change in values over time may be made.

The elements of (3), where the nominal values of the reference cells are set back to their ideal level at the same time the data cells of the word are written.

The elements of (3), where the reader circuitry uses adjusted nominal values derived from the values in reference cells to make a best available decision as to the correct value which was stored in data cells on the same row.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the invention to the specific form or forms disclosed but, on the contrary, the intention is to cover all modifications, alternative constructions, and equivalents falling within the spirit and scope of the invention, as defined in the appended claims.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. Similarly, use of the term “or” is to be construed to mean “and/or” unless contradicted explicitly or by context. The terms “comprising,” “having,” “including,” and “containing” are to be construed as open-ended terms (i.e., meaning “including, but not limited to,”) unless otherwise noted. The term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within the range, unless otherwise indicated herein, and each separate value is incorporated into the specification as if it were individually recited herein. The use of the term “set” (e.g., “a set of items”) or “subset” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but the subset and the corresponding set may be equal. The use of the phrase “based on,” unless otherwise explicitly stated or clear from context, means “based at least in part on” and is not limited to “based solely on.”

Conjunctive language, such as phrases of the form “at least one of A, B, and C,” or “at least one of A, B and C,” (i.e., the same phrase with or without the Oxford comma) unless specifically stated otherwise or otherwise clearly contradicted by context, is otherwise understood within the context as used in general to present that an item, term, etc., may be either A or B or C, any nonempty subset of the set of A and B and C, or any set not contradicted by context or otherwise excluded that contains at least one A, at least one B, or at least one C. For instance, in the illustrative example of a set having three members, the conjunctive phrases “at least one of A, B, and C” and “at least one of A, B and C” refer to any of the following sets: {A}, {B}, {C}, {A, B}, {A, C}, {B, C}, {A, B, C}, and, if not contradicted explicitly or by context, any set having {A}, {B}, and/or {C} as a subset (e.g., sets with multiple “A”). Thus, such conjunctive language is not generally intended to imply that certain embodiments require at least one of A, at least one of B and at least one of C each to be present. Similarly, phrases such as “at least one of A, B, or C” and “at least one of A, B or C” refer to the same as “at least one of A, B, and C” and “at least one of A, B and C” refer to any of the following sets: {A}, {B}, {C}, {A, B}, {A, C}, {B, C}, {A, B, C}, unless differing meaning is explicitly stated or clear from context. In addition, unless otherwise noted or contradicted by context, the term “plurality” indicates a state of being plural (e.g., “a plurality of items” indicates multiple items). The number of items in a plurality is at least two but can be more when so indicated either explicitly or by context.

Operations of processes described herein can be performed in any suitable order unless otherwise indicated herein or otherwise clearly contradicted by context. In an embodiment, a process such as those processes described herein (or variations and/or combinations thereof) is performed under the control of one or more computer systems configured with executable instructions and is implemented as code (e.g., executable instructions, one or more computer programs or one or more applications) executing collectively on one or more processors, by hardware or combinations thereof. In an embodiment, the code is stored on a computer-readable storage medium, for example, in the form of a computer program comprising a plurality of instructions executable by one or more processors. In an embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In an embodiment, code (e.g., executable code or source code) is stored on a set of one or more non-transitory computer-readable storage media having stored thereon executable instructions that, when executed (i.e., as a result of being executed) by one or more processors of a computer system, cause the computer system to perform operations described herein. The set of non-transitory computer-readable storage media, in an embodiment, comprises multiple non-transitory computer-readable storage media, and one or more of individual non-transitory storage media of the multiple non-transitory computer-readable storage media lack all of the code while the multiple non-transitory computer-readable storage media collectively store all of the code. In an embodiment, the executable instructions are executed such that different instructions are executed by different processors—for example, in an embodiment, a non-transitory computer-readable storage medium stores instructions and a main CPU executes some of the instructions while a graphics processor unit executes other instructions. In another embodiment, different components of a computer system have separate processors and different processors execute different subsets of the instructions.

Accordingly, in an embodiment, computer systems are configured to implement one or more services that singly or collectively perform operations of processes described herein, and such computer systems are configured with applicable hardware and/or software that enable the performance of the operations. Further, a computer system, in an embodiment of the present disclosure, is a single device and, in another embodiment, is a distributed computer system comprising multiple devices that operate differently such that the distributed computer system performs the operations described herein and such that a single device does not perform all operations.

The use of any and all examples or exemplary language (e.g., “such as”) provided herein is intended merely to better illuminate embodiments of the invention and does not pose a limitation on the scope of the invention unless otherwise claimed. No language in the specification should be construed as indicating any non-claimed element as essential to the practice of the invention.

Embodiments of this disclosure are described herein, including the best mode known to the inventors for carrying out the invention. Variations of those embodiments may become apparent to those of ordinary skill in the art upon reading the foregoing description. The inventors expect skilled artisans to employ such variations as appropriate, and the inventors intend for embodiments of the present disclosure to be practiced otherwise than as specifically described herein. Accordingly, the scope of the present disclosure includes all modifications and equivalents of the subject matter recited in the claims appended hereto as permitted by applicable law. Moreover, any combination of the above-described elements in all possible variations thereof is encompassed by the scope of the present disclosure unless otherwise indicated herein or otherwise clearly contradicted by context.

All references including publications, patent applications, and patents cited herein are hereby incorporated by reference to the same extent as if each reference were individually and specifically indicated to be incorporated by reference and were set forth in its entirety herein.

What is claimed is:

1. A memory system comprising:
a memory string comprising a plurality of dynamic memory cells, wherein each of the plurality of dynamic memory cells is formed on a substrate and comprises:
an access transistor connecting via a channel of the access transistor a data input line to a capacitive element storing a charge which represents a value, the access transistor formed on the substrate;
an output transistor connected via a gate of the output transistor to the capacitive element, the output transistor formed in a layer located above the substrate, wherein the output transistors of the plurality of dynamic memory cells have channels connected in series in the layer to form a stacked-gate transistor; and
a read select line connected to the capacitive element, wherein a change in voltage on the read-select line controls the voltage on the capacitive element;
a read string select line connecting in series the channels of the output transistors of each of the plurality of dynamic memory cells; and
a data output line connected to the stacked-gate transistor, wherein to access data stored in cells of the plurality of cells, the read select line of the cells is set to a neutral level to cause the output of the output transistor of the cells to be detectable, wherein the output of the cells is output on the data output line.

2. The system of claim 1, where the capacitive element is formed above the substrate, and wherein a portion of the capacitive element comprises at least a portion of the gate of the output transistor.

3. The system of claim 1, wherein the read select line comprises a portion of the capacitive element, such that a voltage applied to the gate of the output transistor is modulated by a voltage of the read select line and the charge stored in the capacitive element.

4. The system of claim 3, wherein the read select line of a dynamic memory cell of the plurality of dynamic memory cells defaults to a first voltage level when not selected, wherein the first voltage level applied to the gate of the output transistor allows the channel of the output transistor of the dynamic memory cell to be conductive independent of the charge stored in the capacitive element.

5. The system of claim 3, wherein a second voltage level applied to the read select line of the dynamic memory cell causes the output transistor to inhibit current flow, and output the value stored in the capacitive element.

6. The system of claim 4, wherein the read select lines of the plurality of memory cells are set to the first voltage level when data is being stored in at least one capacitive element of the plurality of memory cells.

7. The system of claim 3, wherein the second voltage level is applied to the read select line of the dynamic memory cell contemporaneously with the charge being stored in the capacitive element of the dynamic memory cell.

8. The system of claim 7, further comprising a feedback circuit connected to the data output line, wherein the feedback circuit obtains the charge being stored in the capacitive element to calibrate the value associated with the charge stored in the dynamic memory cell upon the second voltage level being applied to the read select line.

9. The system of claim 1, further comprising a feedback loop connected to the data output line, wherein the feedback loop is configured to concurrently adjust a value written to one of the plurality of dynamic memory cells to converge on a nominal output voltage representing the value which the dynamic memory cell is to hold.

10. The system of claim 1, wherein the output transistor, the data output line, and the read select line are formed substantially above the access transistor and the capacitive element.

11. A memory system comprising:
a memory string comprising a plurality of memory cells, wherein each of the plurality of memory cells comprises:
an access transistor connected via a channel of the access transistor to a data line, the access transistor controlled by a write select line connected to a gate of the access transistor;
a capacitive element connected to the channel of the access transistor via a first side of the capacitive element such that the access transistor controls current flow between the data line and the capacitive element, the capacitive element storing a charge representing a value;
a read select line connected to the capacitive element via a second side of the capacitive element opposite the first side; and
a sense transistor connected via a gate of the sense transistor to the first side of the capacitive element such that the charge stored in the capacitive element and a first voltage on the read select line control a third voltage on the gate of the sense transistor, a channel of the sense transistor modulated by the third voltage on the gate of the sense transistor and formed on the data line, sense transistors of the plurality of dynamic memory cells having channels connected in series to form a stacked-gate transistor that forms part of the data line; and
a read string select line connected to the channels of the sense transistors of the plurality of dynamic memory cells and providing a power signal to the sense transistors such that the sense transistors modulate the power signal according to the charge stored in the capacitive element of the memory cells, wherein upon writing a value to memory cell, the read string select line of the memory cell provides the input signal to the capacitive element via the access transistor.

12. The system of claim 11, wherein the data line and the stacked gate transistor comprise a single semiconductor element functioning as a data input line and a data output line.

13. The system of claim 11, wherein the capacitive element may hold any of a plurality of different charge levels, representing one or more bits of information.

14. The system of claim 11, wherein upon activation of the write select line for a memory cell, the access transistor becomes conductive and connects the first side of the capacitive element to the data line to allow the charge representing the value to be stored in the capacitive element.

15. The system of claim 11, wherein upon application of an active voltage to the read select line, the charge stored in the capacitive element modulates the sense transistor between conduction and blocking the data line and outputs the charge stored in the capacitive element on the data line.

16. The system of claim 11, wherein upon an active voltage being applied to the read select line for a first memory cell of the plurality of memory cells and upon the write select line for a second memory cell of the plurality of memory cells being activated, the first memory cell is read contemporaneously with the second memory cell being written to.

17. The system of claim 13, wherein the active voltage is applied to the read select line of a first memory cell of the plurality of memory cells contemporaneously with the charge being stored in the capacitive element of the first memory cell.

18. The system of claim 17, further comprising a feedback circuit connected to the data line, wherein the feedback circuit obtains the charge being stored in the capacitive element to calibrate the value associated with the charge stored in the memory cell upon the active being applied to the read select line.

19. The system of claim 11, further comprising a feedback loop connected to the data line, wherein the feedback loop is configured to concurrently adjust a value written to one of the plurality of memory cells to converge on a nominal output voltage representing the value which the memory cell is to hold.

20. The system of claim 20, wherein at least one of the plurality of memory cells comprises a reference memory cell, wherein changes in the charge stored in the memory reference cell over a period of time are used to calibrate a relationship between the charge stored in memory cells of the plurality of memory cells and the value represented by the charge.
